(19) United States
(12) Patent Application Publication
(10) Pub. No.: US 2025/0126775 A1
(43) Pub. Date: Apr. 17, 2025

(54) SEMICONDUCTOR DEVICES

(71) Applicant: SAMSUNG ELECTRONICS CO., LTD., Suwon-si (KR)

(72) Inventors: Sangho LEE, Suwon-si (KR); Moonyoung JEONG, Suwon-si (KR)

(21) Appl. No.: 18/635,612

(22) Filed: Apr. 15, 2024

(30) Foreign Application Priority Data
Oct. 16, 2023 (KR) 10-2023-0138014

(51) Int. Cl. H10B 12/00

(52) U.S. Cl. CPC H10B 12/482; H10B 12/315; H10B 12/488

(57) ABSTRACT

Disclosed is a semiconductor device comprising: first and second gate structures adjacent to each other; a first active pillar and a second active pillar between the first gate structure and the second gate structure; a channel capping layer between the first active pillar and the second active pillar; and a bit-line structure in contact with the first active pillar, the second active pillar, and the channel capping layer, wherein each of the first and second gate structures includes: a first word line and a second word line that are spaced apart from each other; a gate dielectric layer in contact with the first word line and the second word line; and a gate capping layer in contact with the gate dielectric layer and spaced apart from the first word line and the second word line, and wherein the gate capping layer is in contact with the bit-line structure.

### REFERENCE TO RELATED APPLICATIONS

This U.S. nonprovisional application claims priority under 35 U.S.C § 119 to Korean Patent Application No. 10-2023-0138014 filed on Oct. 16, 2023 in the Korean Intellectual Property Office, the disclosure of which is hereby incorporated by reference in its entirety.

### BACKGROUND OF THE INVENTION

The present inventive concepts relate to semiconductor devices, and more particularly, to semiconductor devices including vertical channel transistors.

A reduction in design rule of semiconductor devices induces development of fabrication technology to increase integration, operating speeds, and manufacturing yield of semiconductor devices. Accordingly, transistors with vertical channels have been suggested to increase their integration, resistance, current driving capability, etc.

### SUMMARY OF THE INVENTION

Some embodiments of the present inventive concepts provide semiconductor devices with improved electrical properties.

According to some embodiments of the present inventive concepts, a semiconductor device may comprise: a first gate structure and a second gate structure that are adjacent to each other in a first direction; a first active pillar and a second active pillar between the first gate structure and the second gate structure; a channel capping layer between the first active pillar and the second active pillar; and a bit-line structure that is in contact with the first active pillar, the second active pillar, and the channel capping layer, wherein each of the first and second gate structures includes: a first word line and a second word line that are spaced apart from each other in the first direction; a gate dielectric layer that is in contact with the first word line and the second word line; and a gate capping layer that is in contact with the gate dielectric layer and spaced apart from the first word line and the second word line in a second direction that is perpendicular to the first direction, and wherein the gate capping layer is in contact with the bit-line structure.

According to some embodiments of the present inventive concepts, a semiconductor device may comprise: a first channel structure and a second channel structure that are adjacent to each other in a first direction; a gate dielectric layer in contact with the first and second channel structures; a first word line on a first inner sidewall of the gate dielectric layer; a second word line on a second inner sidewall of the gate dielectric layer; and a gate capping layer spaced apart from the first and second word lines in a second direction that is perpendicular to the first direction, wherein each of the first and second channel structures includes: a first active pillar and a second active pillar that are spaced apart from each other in the first direction; and a channel capping layer between the first and second active pillars in the first direction, wherein the gate capping layer is in contact with the first and second inner sidewalls of the gate dielectric layer.

According to some embodiments of the present inventive concepts, a semiconductor device may comprise: a bit-line structure; a first gate structure and a second gate structure on the bit-line structure; a first active pillar and a second active pillar between the first gate structure and the second gate structure in a first direction; a channel capping layer between the first active pillar and the second active pillar; a data contact that is electrically connected to each of the first and second active pillars; a landing pad that is electrically connected to the data contact; and a data storage pattern that is electrically connected to the landing pad, wherein each of the first and second gate structures includes: a first word line and a second word line that are spaced apart from each other in the first direction; a gate dielectric layer that is in contact with the first word line and the second word line; and a gate capping layer that is in contact with the gate dielectric layer and spaced apart from the first word line and the second word line in a second direction that is perpendicular to the first direction, wherein a lower surface of the channel capping layer is coplanar with a lower surface of the gate capping layer.

### BRIEF DESCRIPTION OF THE DRAWINGS

FIG. 1A illustrates a block diagram showing a semiconductor device according to some embodiments.

FIGS. 1B and 1C illustrate simplified perspective views showing a semiconductor device according to some embodiments.

FIG. 2A illustrates a plan view showing a semiconductor device according to some embodiments.

FIG. 2B illustrates a cross-sectional view taken along line A-A′ of FIG. 2A.

FIG. 2C illustrates an enlarged view showing section E1 of FIG. 2B.

FIGS. 3A to 30B illustrate diagrams showing a method of fabricating a semiconductor device according to some embodiments.

FIG. 31 illustrates a cross-sectional view showing a semiconductor device according to some embodiments.

FIG. 32 illustrates a cross-sectional view showing a semiconductor device according to some embodiments.

FIG. 33 illustrates a cross-sectional view showing a semiconductor device according to some embodiments.

FIG. 34 illustrates a cross-sectional view showing a semiconductor device according to some embodiments.

FIG. 35 illustrates a cross-sectional view showing a semiconductor device according to some embodiments.

### DETAILED DESCRIPTION

It will be hereinafter discussed a semiconductor device and a method of fabricating the same according to some embodiments of the present inventive concept in conjunction with the accompanying drawings.

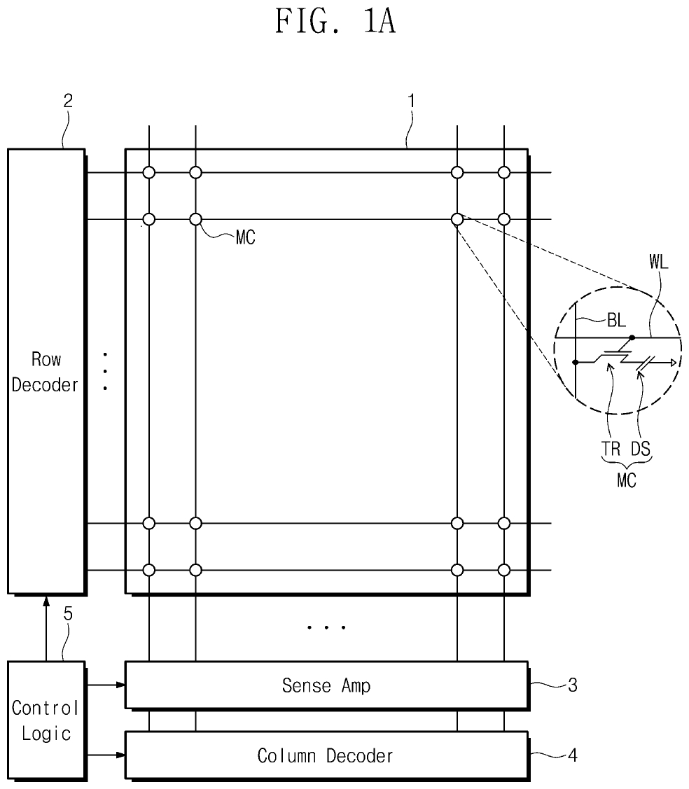

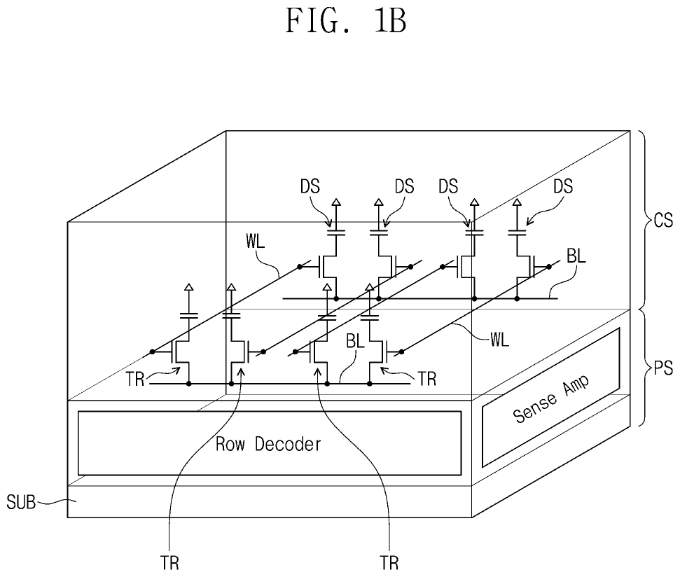

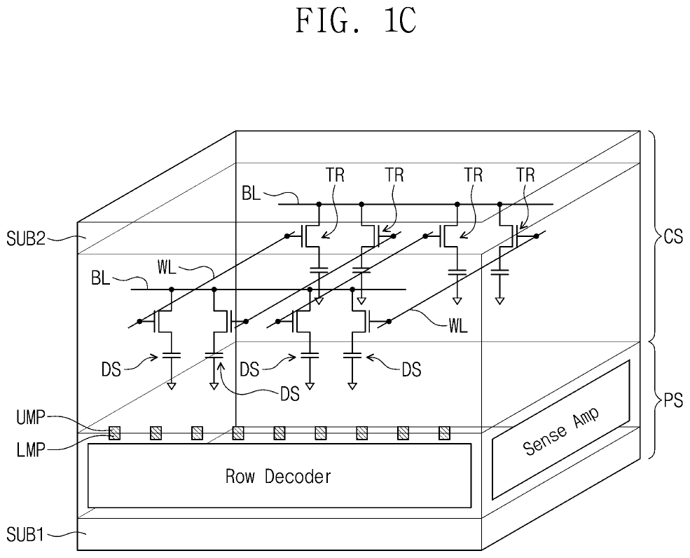

FIG. 1A illustrates a block diagram showing a semiconductor device according to some embodiments.

Referring to FIG. 1, a semiconductor device may include a memory cell array 1, a row decoder 2, a sense amplifier 3, a column decoder 4, and a control logic 5.

The memory cell array 1 may include a plurality of memory cells MC that are arranged two-dimensionally or three-dimensionally. Each of the memory cells MC may be provided between a word line WL and a bit line BL that intersect each other (in a plan view). Each of the memory cells MC may be connected (e.g., electrically connected) to the word line WL and the bit line BL. It will be understood that when an element or layer is referred to as being “connected to”, or “coupled to”, another element or layer, it may be directly on, connected to, or coupled to the other element or layer, or one or more intervening elements or layers may be present. In contrast, when an element is referred to as being “directly coupled,” “directly connected,” or “directly responsive” to, or “directly on,” another element, there are no intervening elements present. In addition, “electrical connection” conceptually includes a physical connection or a physical disconnection.

Each of the memory cells MC may include a selection element TR and a data storage element DS. The selection element TR and the data storage element DS may be electrically connected to each other. The selection element TR may be connected (e.g., electrically connected) to both of the word line WL and the bit line BL. For example, the selection element TR may be provided at an intersection between the word line WL and the bit line BL (in a plan view).

The selection element TR may include a field effect transistor. The data storage element DS may include a capacitor, a magnetic tunnel junction pattern, or a variable resistor. For example, a gate terminal of the transistor as the selection element TR may be connected (e.g., electrically connected) to the word line WL, and source/drain terminals of the transistor may be connected (e.g., electrically connected) to the bit line BL and the data storage element DS.

The row decoder 2 may decode an address that is externally input and may select one of the word lines WL of the memory cell array 1. The address decoded in the row decoder 2 may be provided to a row driver (not shown), and in response to a control operation of control circuits, the row driver may provide a certain voltage to a selected word line WL and each of non-selected word lines WL. As used hereinafter, the terms “external/outside configuration”, “external/outside device”, “external/outside power”, “external/outside signal”, or “outside” are intended to broadly refer to a device, circuit, block, module, power, and/or signal that resides externally (e.g., outside of a functional or physical boundary) with respect to a given circuit, block, module, system, or device.

In response to an address that is decoded from the column decoder 4, the sense amplifier 3 may detect and amplify a voltage difference between a selected bit line BL and a reference bit line, and may then output the amplified voltage difference.

The column decoder 4 may provide a data delivery pathway between the sense amplifier 3 and an external device (e.g., a memory controller). The column decoder 4 may decode an address that is externally input and may select one of the bit lines BL.

The control logic 5 may generate control signals that control operations to write data to the memory cell array 1 and/or to read data from the memory cell array 1. As used herein, the term “and/or” includes any and all combinations of one or more of the associated listed items. Expressions such as “at least one of,” when preceding a list of elements, modify the entire list of elements and do not modify the individual elements of the list.

FIGS. 1B and 1C illustrate simplified perspective views showing a semiconductor device according to some embodiments.

Referring to FIGS. 1B and 1C, a semiconductor device may include a peripheral circuit structure PS and a cell array structure CS connected (e.g., electrically connected) to the peripheral circuit structure PS.

The peripheral circuit structure PS may include core/peripheral circuits formed on a substrate SUB. The core/peripheral circuits may include the row decoder 2, the column decoder 4 (not shown in FIGS. 1B and 1C), the sense amplifier 3, and the control logic 5 (not shown in FIGS. 1B and 1C) that are discussed with reference to FIG. 1A.

The cell array structure CS may include the memory cell array 1 (see FIG. 1A) including the memory cells MC (see FIG. 1A) arranged two-dimensionally or three-dimensionally. Each of the memory cells MC (see FIG. 1A) may include, as discussed above, the selection element TR and the data storage element DS.

In some embodiments, a vertical channel transistor (VCT) may be included as the selection element TR of each memory cell MC (see FIG. 1A). The vertical channel transistor may include a channel whose lengthwise direction is perpendicular to an upper surface of the substrate SUB. The data storage element DS of each memory cell MC (see FIG. 1A) may include a capacitor.

In the embodiment of FIG. 1B, the peripheral circuit structure PS may be provided on the substrate SUB, and the cell array structure CS may be provided on the peripheral circuit structure PS.

In the embodiment of FIG. 1C, the peripheral circuit structure PS may be provided on a first substrate SUB1, and the cell array structure CS may be provided on a second substrate SUB2. The first substrate SUB1 and the second substrate SUB2 may face each other. For example, an upper surface of the first substrate SUB1 and a lower surface of the second substrate SUB2 may face each other. The peripheral circuit structure PS may be on the upper surface of the first substrate SUB1. The cell array structure CS may be on the lower surface of the second substrate SUB2.

The peripheral circuit structure PS may be provided on its upper (e.g., uppermost) portion with first metal pads LMP. The first metal pads LMP may be electrically connected to the core/peripheral circuits (see 2, 3, 4, and 5 of FIG. 1A).

The cell array structure CS may be provided on its lower (e.g., lowermost) portion with second metal pads UMP. The second metal pads UMP may be electrically connected to the memory cell array 1 (see FIG. 1A). The second metal pads UMP of the cell array structure CS may be in direct contact with or bonded to the first metal pads LMP of the peripheral circuit structure PS.

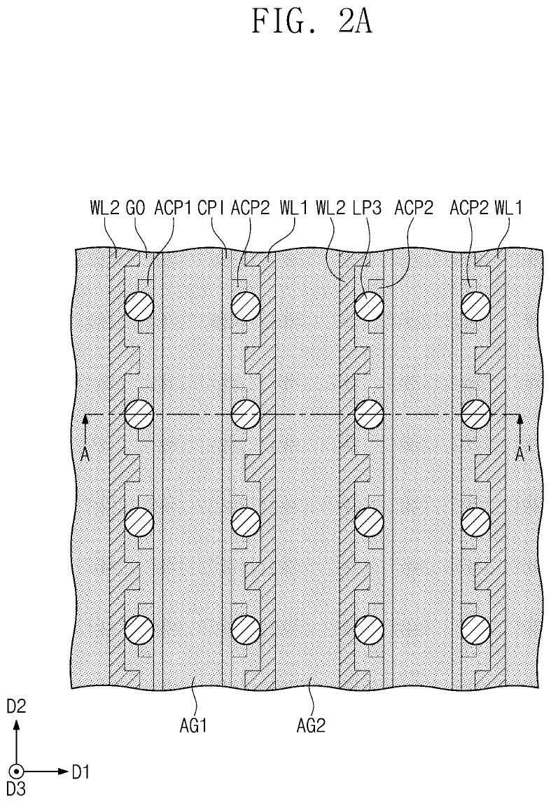

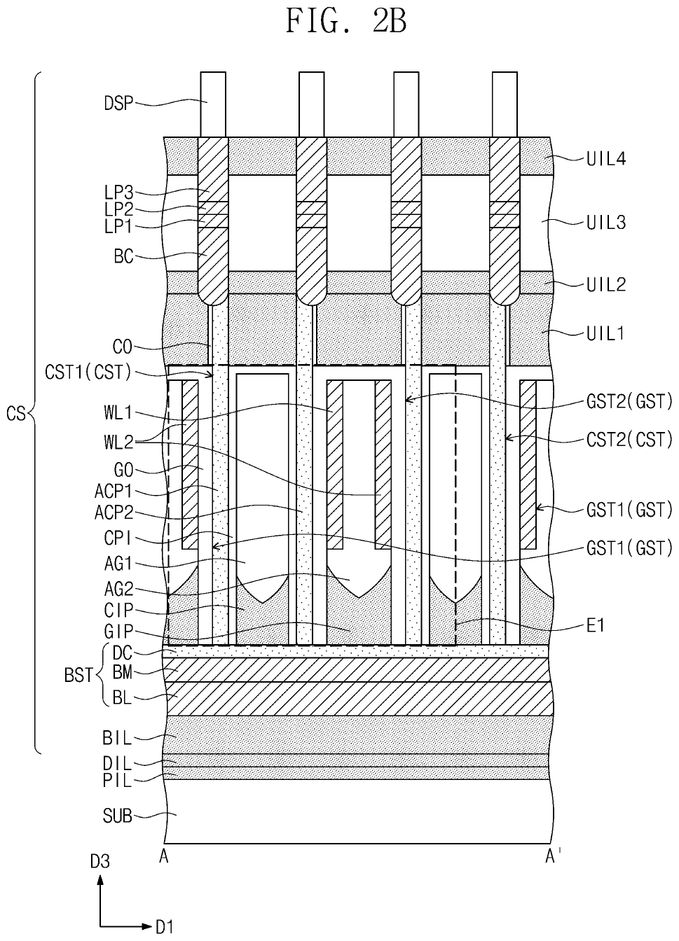

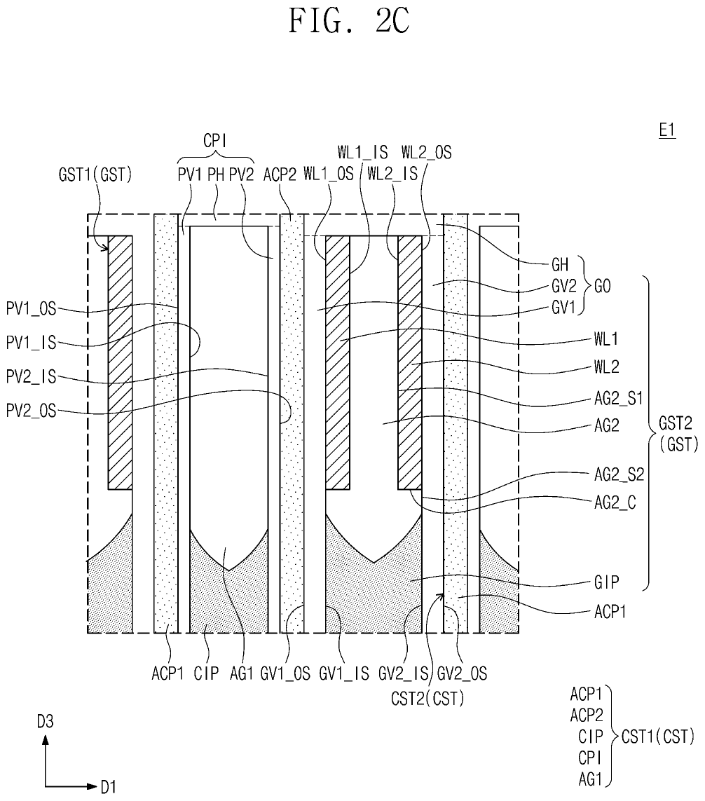

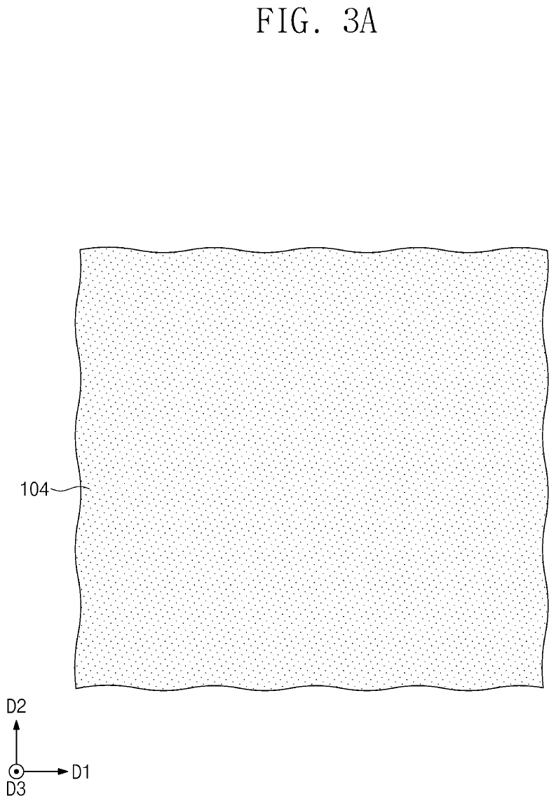

FIG. 2A illustrates a plan view showing a semiconductor device according to some embodiments. FIG. 2B illustrates a cross-sectional view taken along line A-A′ of FIG. 2A. FIG. 2C illustrates an enlarged view showing section E1 of FIG. 2B.

Referring to FIGS. 2A to 2C, a peripheral circuit dielectric layer PIL may be provided on a substrate SUB. The substrate SUB may have a plate shape elongated along a plane defined by a first direction D1 and a second direction D2. The first direction D1 and the second direction D2 may intersect each other. For example, the first direction D1 and the second direction D2 may be horizontal directions that are orthogonal to each other. The peripheral circuit dielectric layer PIL may include a dielectric material. For example, the peripheral circuit dielectric layer PIL may include nitride.

In some embodiments, the substrate SUB and the peripheral circuit dielectric layer PIL may be provided therebetween with a peripheral circuit structure PS discussed with reference to FIG. 1B. In some embodiments, an integrated circuit, such as a logic element, may be provided between the substrate SUB and the peripheral circuit dielectric layer PIL.

A lower dielectric layer DIL may be provided on the peripheral circuit dielectric layer PIL. In some embodiments, the peripheral circuit dielectric layer PIL and the lower dielectric layer DIL may be bonded to each other by a wafer bonding process.

A cell array structure CS may be provided on the lower dielectric layer DIL. The cell array structure CS may include memory cells including vertical channel transistors. The cell array structure CS may include a bit-line dielectric layer BIL, a bit-line structure BST, channel structures CST, gate structures GST, support dielectric layers CO, upper dielectric layers UIL1, UIL2, UIL3, and UIL4, data contacts BC, landing pads LP1, PL2, and LP3, and data storage patterns DSP.

The bit-line dielectric layer BIL may be provided on the lower dielectric layer DIL. The bit-line dielectric layer BIL may extend in a first direction D1. The bit-line dielectric layer BIL may include a dielectric material. For example, the bit-line dielectric layer BIL may include nitride. In some embodiments, the bit-line dielectric layer BIL may be provided in plural. The plurality of bit-line dielectric layers BIL may be disposed spaced apart from each other in a second direction D2.

The bit-line structure BST may be provided on the bit-line dielectric layer BIL. The bit-line structure BST may include a bit line BL, a barrier layer BM, and a connection layer DC.

The bit line BL may be provided to contact the bit-line dielectric layers BIL. The bit line BL may extend in the first direction D1. In some embodiments, the bit line BL may be provided in plural. The plurality of bit lines BL may be disposed spaced apart from each other in the second direction D2.

The bit line BL may include a conductive material. The bit line BL may include, for example, doped polysilicon, metal (e.g., Al, Cu, Ti, Ta, Ru, W, Mo, Pt, Ni, and/or Co), conductive metal nitride (e.g., TiN, TaN, WN, NbN, TiAlN, TiSiN, TaSiN, and/or RuTiN), conductive metal silicide, and/or conductive metal oxide (e.g., PtO, RuO₂, IrO₂, SRO(SrRuO₃), BSRO((Ba,Sr)RuO₃), CRO(CaRuO₃), and/or LSCo), but the present inventive concepts are not limited thereto. The bit line BL may have a single or multiple layer including the material discussed above. In some embodiments, the bit line BL may include a two-dimensional semiconductor material, such as graphene, carbon nano-tube, or any combination thereof.

The barrier layer BM may be provided on the bit line BL. The barrier layer BM may extend in the first direction D1. In some embodiments, the barrier layer BM may include a plurality of layers. The barrier layer BM may be in contact with the bit line BL. The barrier layer BM may include a conductive material. For example, the barrier layer BM may include TiN. In some embodiments, the barrier layer BM may be provided in plural. The plurality of barrier layers BM may be disposed spaced apart from each other in the second direction D2.

The connection layer DC may be provided on the barrier layer BM. The connection layer DC may extend in the first direction D1. In some embodiments, the connection layer DC may include a plurality of layers. The connection layer DC may electrically connect the bit line BL to an active pillar ACP1 or ACP2 which will be discussed below. The connection layer DC may include a conductive material. For example, the connection layer DC may include doped silicon. In some embodiments, the connection layer DC may be provided in plural. The plurality of connection layers DC may be disposed spaced apart from each other in the second direction D2.

The channel structures CST and the gate structures GST may be provided on the connection layer DC. The channel structures CST may be disposed spaced apart from each other in the first direction D1. The channel structures CST and the gate structures GST may extend in the second direction D2. The gate structure GST may be disposed between the channel structures CST that are adjacent to each other in the first direction D1. The channel structures CST that are adjacent to each other in the first direction D1 may be spaced apart from each other across the gate structure GST. The channel structures CST and the gate structures GST may be disposed alternately with each other (in the first direction D1).

The channel structures CST may include a first channel structure CST1 and a second channel structure CST2 that are adjacent to each other. Each of the first and second channel structures CST1 and CST2 may include first active pillars ACP1, second active pillars ACP2, a channel protection pattern CPI, and a channel capping layer CIP. The first active pillars ACP1, the second active pillars ACP2, the channel protection pattern CPI, and the channel capping layer CIP that are included in one channel structure CST may be provided between the gate structures GST that are adjacent to each other in the first direction D1.

The first and second active pillars ACP1 and ACP2 may be disposed on the active layer DC. One connection layer DC may be in contact with a plurality of active pillars ACP1 and ACP2. The first and second active pillars ACP1 and ACP2 may be disposed in a matrix shape, or spaced apart from each other in the first direction D1 and the second direction D2, on a plurality of bit lines BL. For example, the first and second active pillars ACP1 and ACP2 in one channel structure CST may be spaced apart from each other in the first direction D1 by the channel capping layer CIP, the channel protection pattern CPI, and a channel air gap AG1, which will be described later.

The first and second active pillars ACP1 and ACP2 may each have a tetragonal shape (in a plan view and/or in a cross-sectional view). In some embodiments, a width in the first direction D1 of the active pillar ACP1 or ACP2 may be less than a width in the second direction D2 of the active pillar ACP1 or ACP2. The shape of the active pillar ACP1 or ACP2 is not limited thereto and may be variously changed.

The first and second active pillars ACP1 and ACP2 may include a semiconductor material. The first and second active pillars ACP1 and ACP2 may include an oxide semiconductor that includes, for example, InGaZnO, InGaSiO, InSnZnO, InZnO, ZnO, ZnSnO, ZnON, ZrZnSnO, SnO, HfInZnO, GaZnSnO, AlZnSnO, YbGaZnO, and/or InGaO, but the present inventive concepts are not limited thereto. For example, the first and second active pillars ACP1 and ACP2 may include indium gallium zinc oxide (IGZO). The first and second active pillars ACP1 and ACP2 may have a single or multiple layer of the oxide semiconductor. The first and second active pillars ACP1 and ACP2 may include an amorphous, crystalline, and/or polycrystalline oxide semiconductor. In some embodiments, the first and second active pillars ACP1 and ACP2 may have bandgap energy greater than that of silicon. For example, the first and second active pillars ACP1 and ACP2 may have bandgap energy of (about) 1.5 eV to (about) 5.6 eV. For example, when the first and second active pillars ACP1 and ACP2 have bandgap energy of (about) 2.0 eV to (about) 4.0 eV, the first and second active pillars ACP1 and ACP2 may have a desirable channel performance, but the present inventive concepts are not limited thereto. The first and second active pillars ACP1 and ACP2 may be polycrystalline and/or amorphous, but the present inventive concepts are not limited thereto. In some embodiments, the first and second active pillars ACP1 and ACP2 may include a two-dimensional semiconductor material, such as graphene, carbon nano-tube, or any combination thereof.

The channel protection pattern CPI may be provided between the first active pillar ACP1 and the second active pillar ACP2. The channel capping layer CIP may be between the first active pillar ACP in and the second active pillar ACP2 in the first direction D1. The channel protection pattern CPI may be in contact with the first active pillar ACP1, the second active pillar ACP2, and the channel capping layer CIP. The channel protection pattern CPI may be disposed between the connection layer DC and a first upper dielectric layer UIL1 which will be discussed below. The channel protection pattern CPI may include a dielectric material. For example, the channel protection pattern CPI may include SiOC.

The channel protection pattern CPI may include a first vertical part PV1, a second vertical part PV2, and a horizontal part PH. The first vertical part PV1 and the second vertical part PV2 may be spaced apart from each other in the first direction D1. The horizontal part PH may extend in the first direction D1. The first vertical part PV1 and the second vertical part PV2 may extend in a third direction D3. The third direction D3 may intersect the first direction D1 and the second direction D2. For example, the third direction D3 may be a vertical direction perpendicular to the first direction D1 and the second direction D2.

The first vertical part PV1 of the channel protection pattern CPI may be disposed between the first active pillar ACP1 and the channel capping layer CIP. The first vertical part PV1 of the channel protection pattern CPI may have an outer sidewall PV1_OS in contact with the first active pillar ACP1. The first vertical part PV1 of the channel protection pattern CPI may have an inner sidewall PV1_IS in contact with the channel capping layer CIP. The second vertical part PV2 of the channel protection pattern CPI may be disposed between the second active pillar ACP2 and the channel capping layer CIP. The second vertical part PV2 of the channel protection pattern CPI may have an outer sidewall PV2_OS in contact with the second active pillar ACP2. The second vertical part PV2 of the channel protection pattern CPI may have an inner sidewall PV2_IS in contact with the channel capping layer CIP. The horizontal part PH of the channel protection pattern CPI may connect the first vertical part PV1 and the second vertical part PV2 to each other. The horizontal part PH of the channel protection pattern CPI may have an upper surface in contact with a first upper dielectric layer UIL1 which will be discussed below. The horizontal part PH of the channel protection pattern CPI may have a lower surface that face the channel capping layer CIP. In some embodiments, the lower surface of the horizontal part PH of the channel protection pattern CPI may be at the same distance as upper surfaces of the first and second vertical parts PV1 and PV2 of the channel protection pattern CPI from an upper surface of the connection layer DC in the third direction D3. For example, the lower surface of the horizontal part PH of the channel protection pattern CPI may be in contact with the upper surfaces of the first and second vertical parts PV1 and PV2 of the channel protection pattern CPI.

The channel capping layer CIP may be provided on the connection layer DC. A lower surface of the channel capping layer CIP may be in contact with the upper surface of the connection layer DC. The channel capping layer CIP may be disposed between the first and second active pillars ACP1 and ACP2. The channel capping layer CIP may have sidewalls in contact with the first vertical part PV1 and the second vertical part PV2 of the channel protection pattern CPI. The channel capping layer CIP may include a dielectric material. For example, the channel capping layer CIP may include nitride.

The channel air gap AG1 may be (defined) in the channel structures CST (e.g., the first channel structure CST1 and/or the second channel structure CST2). The channel air gap AG1 may be between the first and second active pillars ACP1 and ACP2 (in the first direction D1). The channel air gat AG1 may be (defined) between the first vertical part PV1 and the second vertical part PV2 of the channel protection pattern CPI (in the first direction D1). The channel air gap AG1 may be (defined) between the horizontal part PH of the channel protection pattern CPI and the channel capping layer CIP (in the third direction D3). The channel air gap AG1 may be surrounded by the channel protection pattern CPI and the channel capping layer CIP. The channel air gap AG1 may be defined by the channel protection pattern CPI and the channel capping layer CIP. An upper surface of the channel air gap AG1 may be defined by the lower surface of the horizontal part PH of the channel protection pattern CPI. For example, at least a portion of the lower surface of the horizontal part PH of the channel protection pattern CPI may be exposed to the channel air gap AG1. The channel air gap AG1 may have sidewalls defined by the inner sidewalls PV1_IS and PV2_IS of the first and second vertical parts PV1 and PV2 of the channel protection pattern CPI. For example, at least portions of the inner sidewalls PV1_IS and PV2_IS of the first and second vertical parts PV1 and PV2 of the channel protection pattern CPI may be exposed to the channel air gap AG1. A lower surface of the channel air gap AG1 may be defined by an upper surface of the channel capping layer CIP. For example, at least a portion of the upper surface of the channel capping layer CIP may be exposed to the channel air gap AG1. The lower surface of the channel air gap AG1 may be curved. The lower surface of the channel air gap AG1 may be convex toward the channel capping layer CIP. For example, the upper surface of the channel capping layer CIP may be concave toward the connection layer DC. The channel air gap AG1 may overlap the channel capping layer CIP (in the first, second, and/or third directions D1, D2, and/or D3). As used herein, “an element A overlapping an element B in a direction X” (or similar language) means that there is at least one line that extends in the direction X and intersects both the elements A and B.

The gate structures GST may include a first gate structure GST1 and a second gate structure GST2 that are adjacent to each other (in the first direction D1). Each of the first and second gate structures GST1 and GST2 may include a first word line WL1, a second word line WL2, a gate dielectric layer GO, and a gate capping layer GIP. The first word line WL1, the second word line WL2, the gate dielectric layer GO, and the gate capping layer GIP that are included in one gate structure GST may be provided between the channel structures CST that are adjacent to each other in the first direction D1.

The first word line WL1 and the second word line WL2 may be provided on the connection layer DC. The first word line WL1 and the second word line WL2 may be spaced apart from the connection layer DC. The first word line WL1 and the second word line WL2 may be spaced apart from each other in the first direction D1. The first word line WL1 and the second word line WL2 may extend in the second direction D2.

The first and second word lines WL1 and WL2 may include a conductive material. The first and second word lines WL1 and WL2 may include, for example, doped polysilicon, metal (e.g., Al, Cu, Ti, Ta, Ru, W, Mo, Pt, Ni, and/or Co), conductive metal nitride (e.g., TiN, TaN, WN, NbN, TiAlN, TiSiN, TaSiN, and/or RuTiN), conductive metal silicide, and/or conductive metal oxide, but the present inventive concepts are not limited thereto. The first and second word lines WL1 and WL2 may have a single or multiple layer including the material discussed above. In some embodiments, the first and second word lines WL1 and WL2 may include a two-dimensional semiconductor material, such as graphene, carbon nano-tube, and/or any combination thereof.

The gate dielectric layer GO may be provided on the upper surface of the connection layer DC. The gate dielectric layer GO may be between the adjacent channel structures CST. For example, the gate dielectric layer GO may be in contact with the channel structures CST that are adjacent to each other (in the first direction D1).

The gate dielectric layer GO may include a dielectric material. The gate dielectric layer GO may include, for example, silicon oxide, silicon oxynitride, and/or high-k dielectric whose dielectric constant is greater than that of silicon oxide. The high-k dielectric may include, for example, metal oxide and/or metal oxynitride. For example, the high-k dielectrics possibly used as the gate dielectric layer GO may include HfO₂, HfSiO, HfSiON, HfTaO, HfTiO, HfZrO, ZrO₂, and/or Al₂O₃, but the present inventive concepts are not limited thereto.

The gate dielectric layer GO may include a first vertical part GV1, a second vertical part GV2, and a horizontal part GH. The first vertical part GV1 and the second vertical part GV2 may be spaced apart from each other in the first direction D1. The horizontal part GH may extend in the first direction D1. The first vertical part GV1 and the second vertical part GV2 may extend in the third direction D3.

The first vertical part GV1 of the gate dielectric layer GO may be disposed between the first word line WL1 and the second active pillar ACP2 of the channel structure CST adjacent thereto. The first vertical part GV1 of the gate dielectric layer GO may have an outer sidewall GV1_OS in contact with the second active pillar ACP2 of the channel structure CST adjacent thereto. The first vertical part GV1 of the gate dielectric layer GO may have an inner sidewall GV1_IS whose portions are in contact with an outer sidewall WL1_OS of the first word line WL1 and with a sidewall of the gate capping layer GIP. The inner sidewall GV1_IS of the first vertical part GV1 of the gate dielectric layer GO may include a portion that is exposed (e.g., exposed to a gate air gap AG2, which will be described below). The second vertical part GV2 of the gate dielectric layer GO may be disposed between the second word line WL2 and the first active pillar ACP1 of the channel structure CST adjacent thereto. The second vertical part GV2 of the gate dielectric layer GO may have an outer sidewall GV2_OS in contact with the first active pillar ACP1 of the channel structure CST adjacent thereto. The second vertical part GV2 of the gate dielectric layer GO may have an inner sidewall GV2_IS whose portions are in contact with an outer sidewall WL2_OS of the second word line WL2 and with a sidewall of the gate capping layer GIP. The inner sidewall GV2_IS of the second vertical part GV2 of the gate dielectric layer GO may include a portion that is exposed (e.g., exposed to the gate air gap AG2, which will be described below). The horizontal part GH of the gate dielectric layer GO may have an upper surface in contact with a first upper dielectric layer UIL1 which will be discussed below. The horizontal part GH of the gate dielectric layer GO may have a lower surface whose portions are in contact with upper surfaces of the first and second word lines WL1 and WL2. The lower surface of the horizontal part GH of the gate dielectric layer GO may include a portion that faces an upper surface of the gate capping layer GIP. In some embodiments, the lower surface of the horizontal part GH of the gate dielectric layer GO may be at the same distance as upper surfaces of the first and second vertical parts GV1 and GV2 of the gate dielectric layer GO from the upper surface of the connection layer DC in the third direction D3. For example, the lower surface of the horizontal part GH of the gate dielectric layer GO may be in contact with the upper surfaces of the first and second vertical parts GV1 and GV2 of the gate dielectric layer GO.

The gate capping layer GIP may be provided on the connection layer DC. A lower surface of the gate capping layer GIP may be in contact with the upper surface of the connection layer DC. The gate capping layer GIP may be interposed between the first vertical part GV1 and the second vertical part GV2 of the gate dielectric layer GO. The gate capping layer GIP may overlap in the third direction D3 with the first and second word lines WL1 and WL2. The gate capping layer GIP may be spaced apart from the first and second word lines WL1 and WL2 (in the third direction D3). The upper surface of the gate capping layer GIP may face the lower surface of the first word line WL1 and the lower surface of the second word line WL2. The gate capping layer GIP may include a dielectric material. For example, the gate capping layer GIP may include nitride.

The gate air gap AG2 may be (defined) in the gate structure GST. The gate air gap AG2 may be between the first vertical part GV1 and the second vertical part GV2 of the gate dielectric layer GO (in the first direction D1). The gate air gap AG2 may be (defined) between the first vertical part GV1 and the second vertical part GV2 of the gate dielectric layer GO (in the first direction D1). The gate air gap AG2 may be (defined) between the first word line WL1 and the second wordline WL2 (in the first direction D1). The gate air gap AG2 may be (defined) between the horizontal part GH of the gate dielectric layer GO and the gate capping layer GIP (in the third direction D3). The gate air gap AG2 may be surrounded by the gate dielectric layer GO, the first word line WL1, the second word line WL2, and the gat capping layer GIP. An upper surface of the gate air gap AG2 may be defined by (a portion of) a lower surface of the horizontal part GH of the gate dielectric layer GO. For example, a portion of the lower surface of the horizontal part GH of the gate dielectric layer GO may be exposed to the gate air gap AG2. The gate air gap AG2 may have first sidewalls AG2_S1 defined by inner sidewalls WL1_IS and WL2_IS of the first and second word lines WL1 and WL2. For example, the inner sidewalls WL1_IS and WL2_IS may be exposed to the gate air gap AG2. The gate air gap AG2 may have connection surfaces AG2_C defined by the lower surfaces of the first and second word lines WL1 and WL2. For example, the lower surfaces of the first and second word lines WL1 and WL2 may be exposed to the gate air gap AG2. The gate air gap AG2 may have second sidewalls AG2_S2 defined by portions of inner sidewalls GV1_IS and GV2_IS of the first and second vertical parts GV1 and GV2 of the gate dielectric layer GO. For example, the portions of the inner sidewalls GV1_IS and GV2_IS of the first and second vertical parts GV1 and GV2 of the gate dielectric layer GO may be exposed to the gate air gap AG2. A lower surface of the gate air gap AG2 may be defined by the upper surface of the gate capping layer GIP. For example, the upper surface of the gate capping layer GIP may be exposed to the gate air gap AG2. The lower surface of the gate air gap AG2 may be curved. The lower surface of the gate air gap AG2 may be convex toward the gate capping layer GIP. For example, the upper surface of the gate capping layer GIP may be concave toward the connection layer DC. The gate air gap AG2 may overlap the gate capping layer GIP (in the first, second, and/or third directions D1, D2, and/or D3).

The upper surface of the channel air gap AG1 may have a width (in the first direction D1) greater than that of the upper surface of the gate air gap AG2. For example, a portion of the lower surface of (the horizontal part PH of) the channel protection pattern CPI, which is exposed to the channel air gap AG1 may have a width in the first direction D1 greater than a width in the first direction D1 of a portion of the lower surface of (the horizontal part GH of) the gate dielectric layer GO exposed to the gate air gap AG2. The upper surface of the channel air gap AG1 may be located at a higher level than that of the upper surface of the gate air gap AG2. For example, the upper surface of the channel air gap AG1 may be farther that the upper surface of the gate air gap AG2 from the upper surface of the connection layer DC in the third direction D3.

The first active pillar ACP1, the second active pillar ACP2, the first vertical part PV1 of the channel protection pattern CPI, the second vertical part PV2 of the channel protection pattern CPI, the channel capping layer CIP, the first vertical part GV1 of the gate dielectric layer GO, the second vertical part GV2 of the gate dielectric layer GO, and the gate capping layer GIP may have their lower surfaces that are coplanar with each other.

A width in the first direction D1 of each of the first and second vertical parts GV1 and GV2 of the gate dielectric layer GO may be greater than a width in the first direction D1 of each of the first and second vertical parts PV1 and PV2 of the channel protection pattern CPI.

There may be provided support dielectric layers CO in contact with an upper portion of the first and/or second active pillar ACP1 and/or ACP2, data contacts BC on the first and/or second active pillar ACP1 and/or ACP2, first landing pads LP1 on the data contacts BC, second landing pads LP2 on the first landing pads LP1, and third landing pads LP3 on the second landing pads LP2.

The support dielectric layer CO may be disposed on (e.g., may overlap in the third direction D3) the gate dielectric layer GO of the gate structure GST. The support dielectric layer CO may include a dielectric material. For example, the support dielectric layer CO may include oxide.

The data contact BC, the first landing pad LP1, the second landing pad LP2, and the third landing pad LP3 may vertically overlap (e.g., may overlap in the third direction D3) the first and/or second active pillar ACP1 and/or ACP2, and may be disposed in a matrix shape or spaced apart from each other in the first direction D1 and the second direction D2. The data contact BC may connect (e.g., electrically connect) the active pillar ACP1 or ACP2 to the landing pads LP1, LP2, and LP3.

The data contact BC may include a conductive material. For example, the data contact BC may include (e.g., may be formed of) doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and/or any combination thereof, but the present inventive concepts are not limited thereto.

When viewed in plan, the first, second, and third landing pads LP1, LP2, and LP3 may be spaced apart from each other in the first and second directions D1 and D2, and may be arranged in a matrix shape, a zigzag shape, a honeycomb shape, or any other suitable shape. When viewed in plan, the first, second, and third landing pads LP1, LP2, and LP3 may each have a circular shape, an oval shape, a rectangular shape, a square shape, a rhombic shape, a hexagonal shape, or any other suitable shape.

The first, second, and third landing pads LP1, LP2, and LP3 may include a conductive material. For example, the first, second, and third landing pads LP1, LP2, and LP3 may include (e.g., may be formed of) doped polysilicon, Al, Cu, Ti, Ta, Ru, W, Mo, Pt, Ni, Co, TiN, TaN, WN, NbN, TiAl, TiAlN, TiSi, TiSiN, TaSi, TaSiN, RuTiN, NiSi, CoSi, IrOx, RuOx, and/or any combination thereof, but the present inventive concepts are not limited thereto.

A first upper dielectric layer UIL1 may be provided between an upper portion of the first active pillar ACP1, an upper portion of the second active pillar ACP2, and the support dielectric layers CO. For example, the upper portions of the first and second active pillars ACP1 and ACP2 and the support dielectric layers CO may extend in the first upper dielectric layer UIL1 (in the third direction D3). The first upper dielectric layer UIL1 may be provided on the channel structures CST and the gate structures GST.

There may be provided a second upper dielectric layer UIL2 on the first upper dielectric layer UIL1, a third upper dielectric layer UIL3 on the second upper dielectric layer UIL2, and a fourth upper dielectric layer UIL4 on the third upper dielectric layer UIL3. The second upper dielectric layer UIL2 may be provided between the data contacts BC. The third upper dielectric layer UIL3 may be provided between the first, second, and third landing pads LP1, LP2, and LP3. The fourth upper dielectric layer UIL4 may be provided between the third landing pads LP3. The data contacts BC may extend in the second upper dielectric layer UIL2 (in the third direction D3). The first, second, and third landing pads LP1, LP2, and LP3 may extend in the third upper dielectric layer UIL3 (in the third direction D3). The third landing pads LP3 may extend in the fourth upper dielectric layer UIL4 (in the third direction D3).

The first, second, third, and fourth upper dielectric layers UIL1, UIL2, UIL3, and UIL4 may separate from each other the data contacts BC, the first landing pads LP1, the second landing pads LP2, and the third landing pads LP3. The first, second, third, and fourth upper dielectric layers UIL1, UIL2, UIL3, and UIL4 may include a dielectric material. For example, each of the first, second, third, and fourth upper dielectric layers UIL1, UIL2, UIL3, and UIL4 may include oxide and/or nitride.

The data storage patterns DSP may be correspondingly provided on the third landing pads LP3. The data storage pattern DSP may be electrically connected to the active pillar ACP1 or ACP2 through the data contact BC and the landing pads LP1, LP2, and LP3.

In some embodiments, the data storage pattern DSP may be a capacitor, which includes a lower electrode, an upper electrode, and a capacitor dielectric layer between the lower and upper electrodes. In this case, the lower electrode may be in contact with the second landing pad LP2, and when viewed in plan, may have a circular shape, an oval shape, a rectangular shape, a square shape, a rhombic shape, a hexagonal shape, or any other suitable shape.

In some embodiments, the data storage pattern DSP may be a variable resistance pattern whose two resistance states are switched due to an electrical pulse. For example, the data storage pattern DSP may include a phase-change material whose crystalline state is changed based on an amount of current, perovskite compounds, transition metal oxide, magnetic materials, ferromagnetic materials, and/or antiferromagnetic materials.

A semiconductor device according to some embodiments may include an air gap that separates neighboring word lines from each other. Therefore, a reduced electrical interference may be between the word lines, and the semiconductor device may improve in electrical properties.

A semiconductor device according to some embodiments may include an air gap between active pillars. Thus, a passing gate effect and an electrical interference between the active pillars may be reduced to improve electrical properties of the semiconductor device.

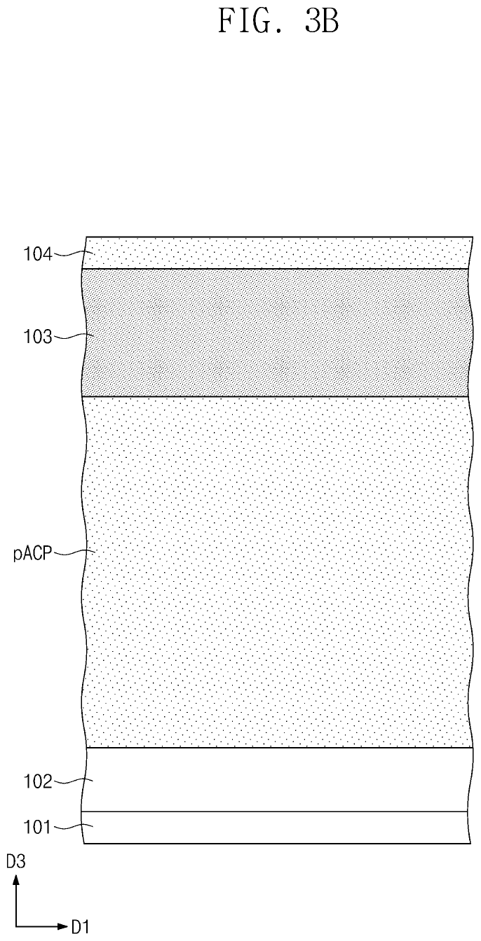

FIGS. 3A to 30B illustrate diagrams showing a method of fabricating a semiconductor device according to some embodiments. FIGS. 3A, 4A, 5A, 6A, 7A, 8A, 9A, 10A, 11A, 12A, 13A, 14A, 15A, 16A, 17A, 18A, 19A, 20A, 22A, 23A, 24A, 25A, 26A, 27A, and 30A illustrate plan views corresponding to that of FIG. 2A. FIGS. 3B, 4B, 5B, 6B, 7B, 8B, 9B, 10B, 11B, 12B, 13B, 14B, 15B, 16B, 17B, 18B, 19B, 20B, 21, 22B, 23B, 24B, 25B, 26B, 27B, 28, 29, and 30B illustrate cross-sectional views corresponding to that of FIG. 2B.

Referring to FIGS. 3A and 3B, there may be formed a wafer substrate 101, a wafer dielectric layer 102 on the wafer substrate 101, a preliminary active pillar pACP on the wafer dielectric layer 102, a first sacrificial layer 103 on the preliminary active pillar pACP, and a first mask layer 104 on the first sacrificial layer 103. For example, the wafer substrate 101 may be a silicon-on-insulator (SOI) substrate or a germanium-on-insulator (GOI) substrate. In some embodiments, the wafer substrate 101 may include silicon, germanium, silicon germanium, gallium phosphorus, and/or gallium arsenic. The wafer dielectric layer 102 and the first sacrificial layer 103 may include a dielectric material. For example, the wafer dielectric layer 102 may include oxide, and the first sacrificial layer 103 may include nitride. For example, the first mask layer 104 may include polysilicon.

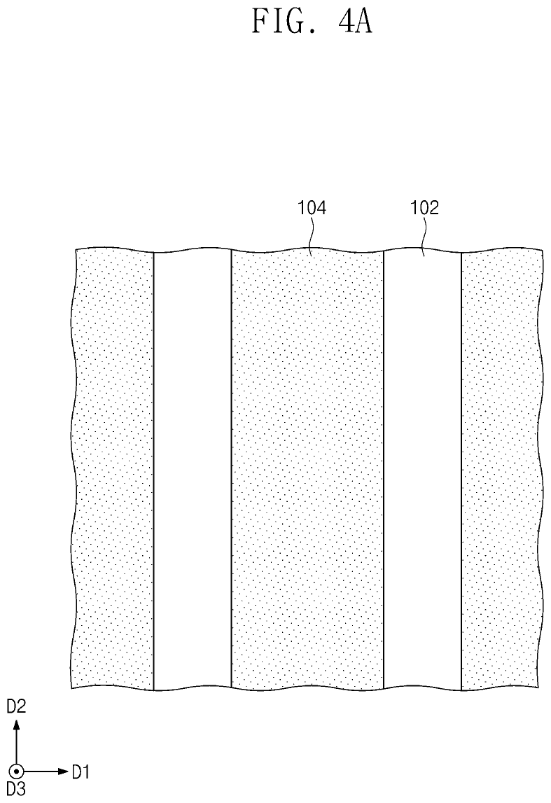

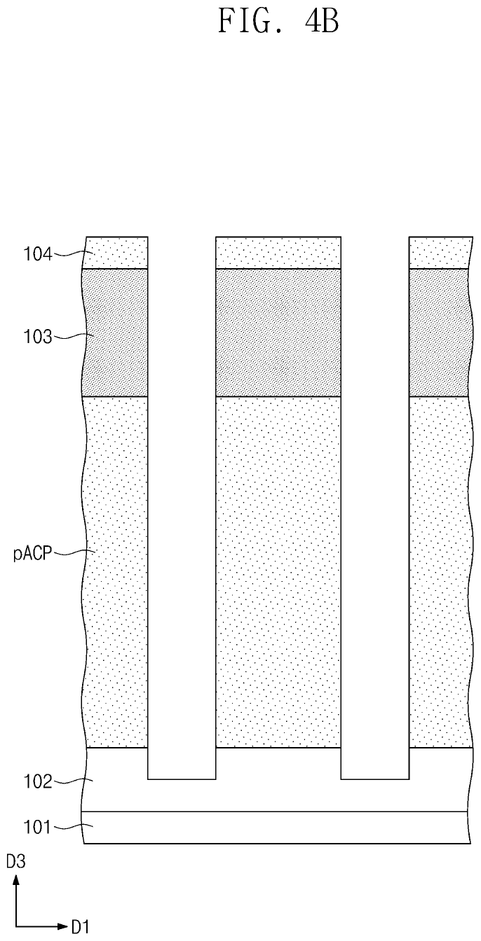

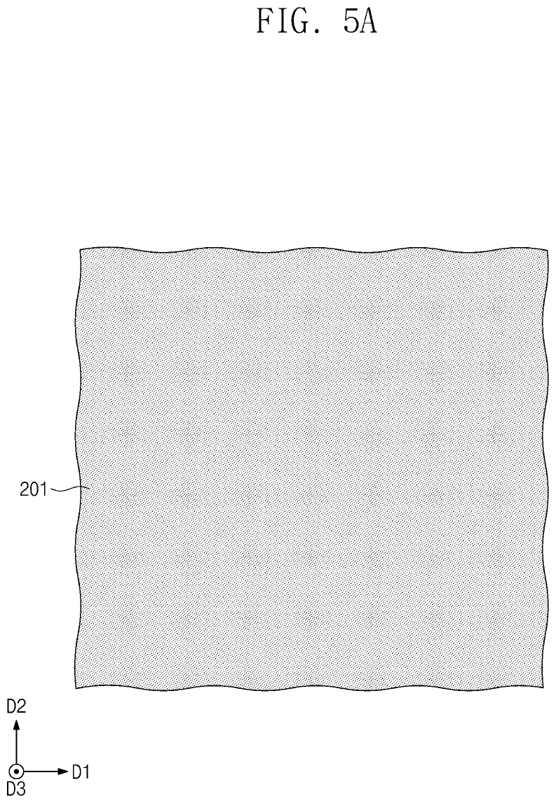

Referring to FIGS. 4A and 4B, a removal action may be performed on a portion of the wafer dielectric layer 102, a portion of the preliminary active pillar pACP, a portion of the first sacrificial layer 103, and a portion of the first mask layer 104. The wafer dielectric layer 102, the preliminary active pillar pACP, the first sacrificial layer 103, and the first mask layer 104 may be partially removed to expose (a portion of) the wafer dielectric layer 102.

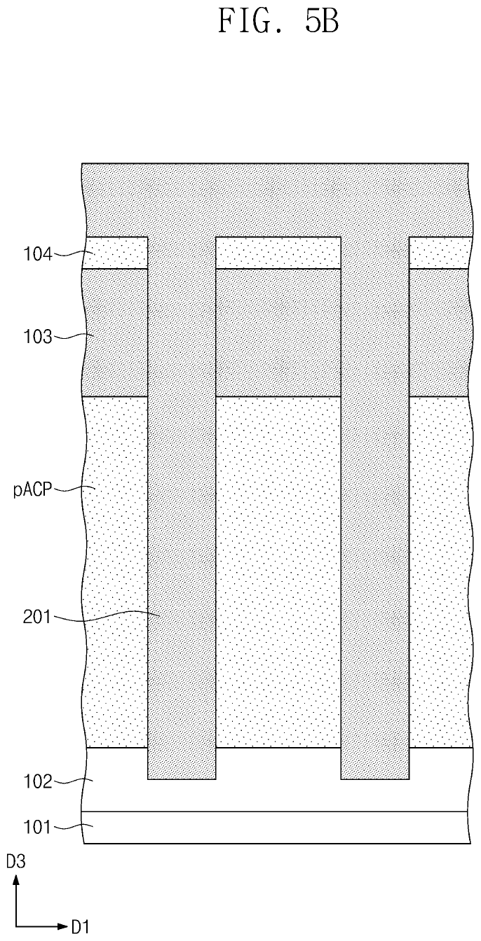

Referring to FIGS. 5A and 5B, a first upper dielectric pattern 201 may be formed to fill an empty space obtained by the partial removal of the wafer dielectric layer 102, the preliminary active pillar pACP, the first sacrificial layer 103, and the first mask layer 104. The first upper dielectric pattern 201 may be on (e.g., cover or overlap) an upper surface of the first mask layer 104. The first upper dielectric pattern 201 may include a dielectric material. For example, the first upper dielectric pattern 201 may include nitride.

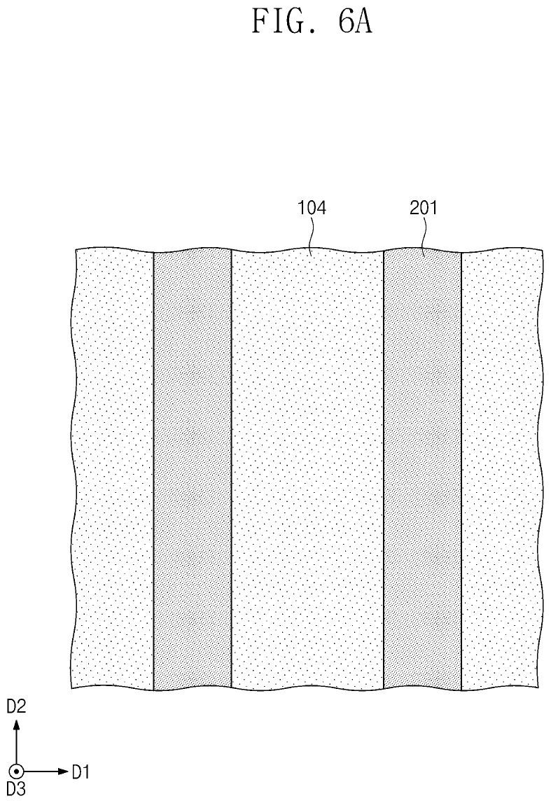

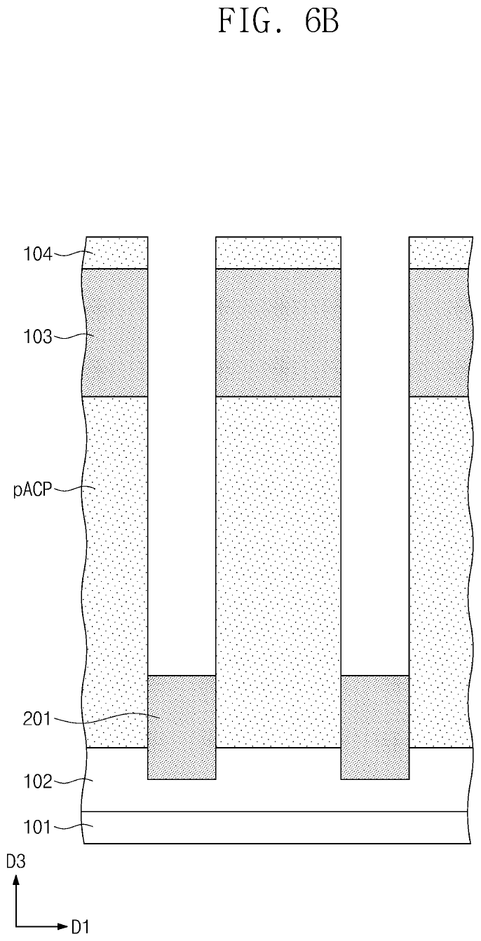

Referring to FIGS. 6A and 6B, an upper portion of the first upper dielectric pattern 201 may be removed. A lower portion of the first upper dielectric pattern 201 may not be removed. A portion (e.g., the upper portion) of the first upper dielectric pattern 201 may be removed to expose (a portion of a sidewall of) the preliminary active pillar pACP, (sidewall of) the first sacrificial layer 103, and (sidewall of) the first mask layer 104. In some embodiments, a portion (e.g., the upper portion) of the first upper dielectric pattern 201 may be removed by an etch-back process.

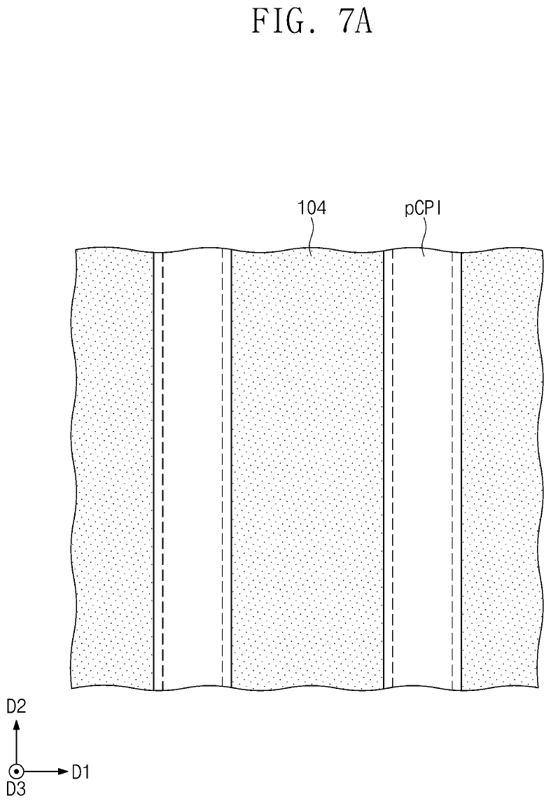

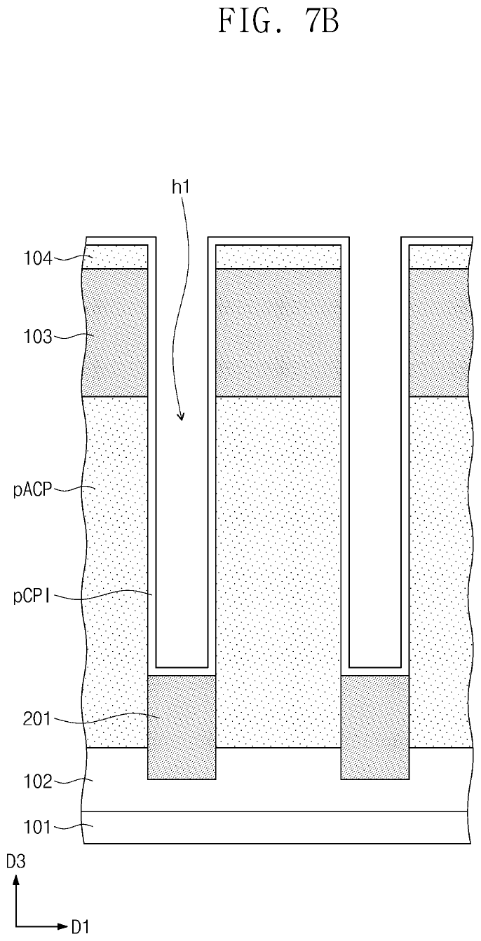

Referring to FIGS. 7A and 7B, a preliminary channel protection pattern pCPI may be formed. The preliminary channel protection pattern pCPI may be conformally formed on (e.g., may conformally cover) (exposed surfaces of) the first upper dielectric pattern 201, the preliminary active pillar pACP, the first sacrificial layer 103, and the first mask layer 104. For example, the preliminary channel protection pattern pCPI may be on an upper surface of the first upper dielectric pattern 201, a sidewall of the preliminary active pillar pACP, a sidewall of the first sacrificial layer 103, a sidewall of the first mask layer 104, and an upper surface of the first mask layer 104. In some embodiments, the preliminary channel protection pattern pCPI may be formed by an atomic layer deposition process. A space h1 may be formed in the preliminary channel protection pattern pCPI. The space h1 in the preliminary channel protection pattern pCPI may be defined by surfaces (e.g., an upper sufrace and sidewalls) of the preliminary channel protection pattern pCPI.

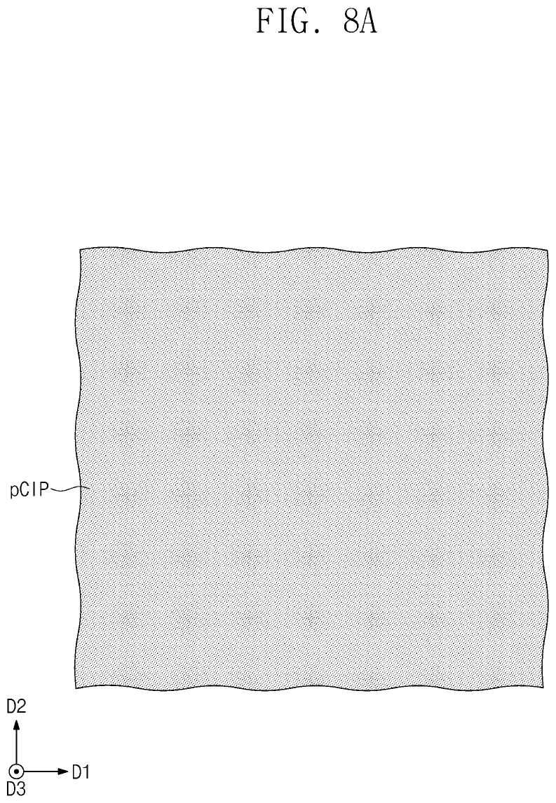

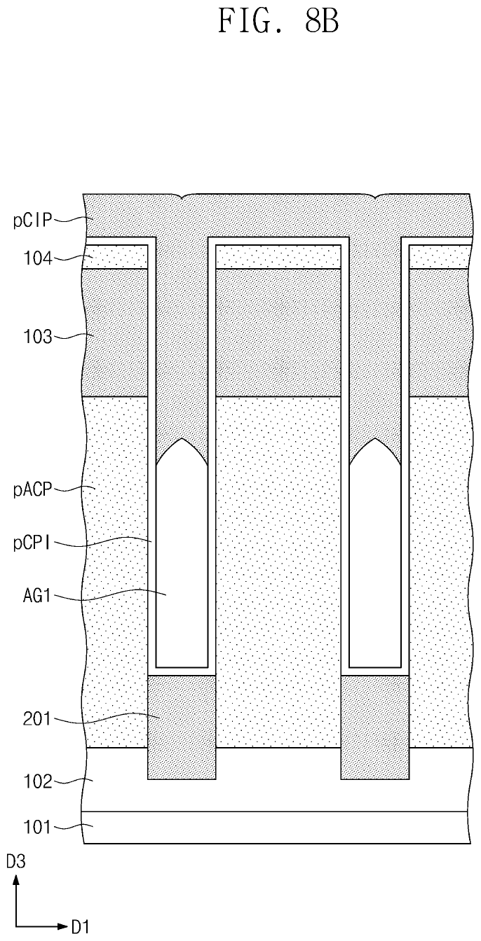

Referring to FIGS. 8A and 8B, a preliminary channel capping layer pCIP may be formed on (a portion of) the preliminary channel protection pattern pCPI. The preliminary channel capping layer pCIP may fill an upper portion of the space h1 in the preliminary channel protection pattern pCPI. The preliminary channel capping layer pCIP may not fill a lower portion of the space h1 in the preliminary channel protection pattern pCPI. A channel air gap AG1 may be defined in the space h1 in the preliminary channel protection pattern pCPI. For example, the channel air gap AG1 may be the lower portion of the space h1 that is not filled with the preliminary channel capping layer pCIP. The channel air gap AG1 may be defined (e.g., surrounded or enclosed) by the preliminary channel capping layer pCIP and the preliminary channel protection pattern pCPI. The preliminary channel capping layer pCIP may include a dielectric material.

In some embodiments, the preliminary channel protection pattern pCPI may be formed by an atomic layer deposition process, and the preliminary channel capping layer pCIP may be formed by a chemical vapor deposition process, with the result that the channel air gap AG1 may be formed.

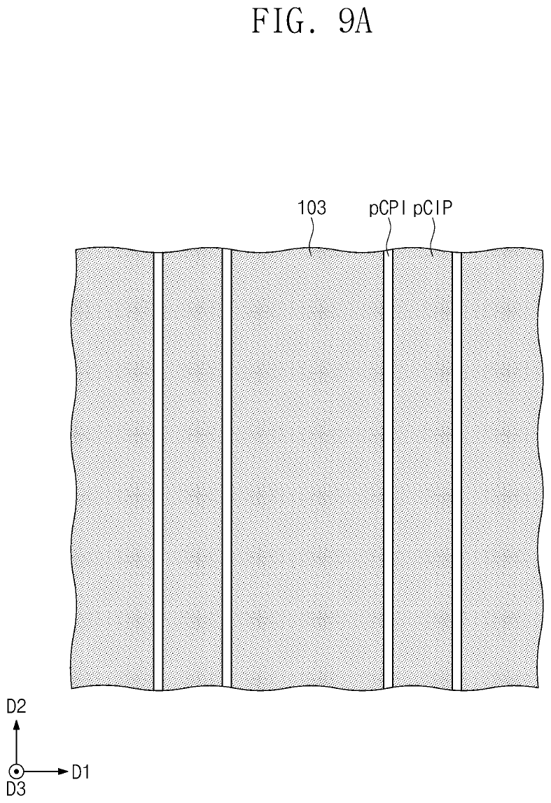

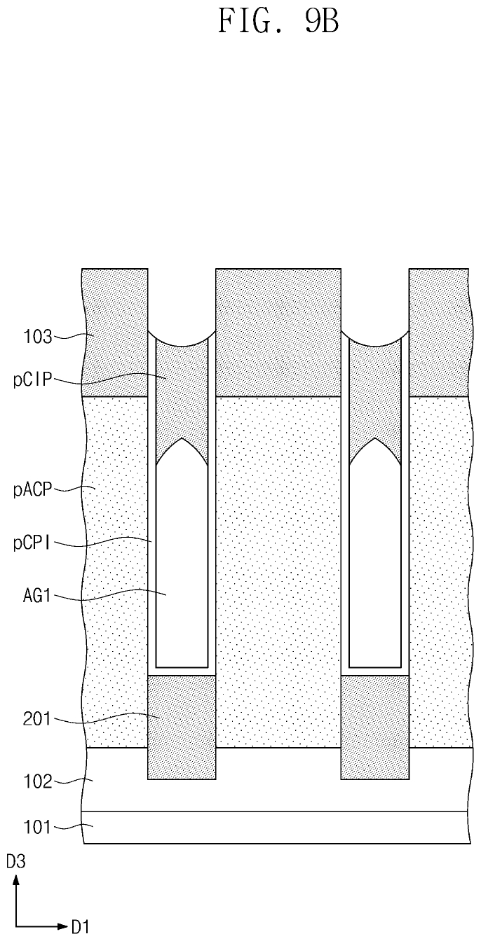

Referring to FIGS. 9A and 9B, there may be removed a portion of the preliminary channel protection pattern pCPI and a portion of the preliminary channel capping layer pCIP. The preliminary channel protection pattern pCPI and the preliminary channel capping layer pCIP may be partially removed to expose (a sidewall of) the first sacrificial layer 103. For example, upper portions of the preliminary channel protection pattern pCPI and the preliminary channel capping layer pCIP may be removed. The first mask layer 104 may be removed during the partial removal process of the preliminary channel protection pattern pCPI and the preliminary channel capping layer pCIP. In some embodiments, a portion (e.g., an upper portion) of the preliminary channel capping layer pCIP may be removed by a chemical mechanical polishing process. In some embodiments, an etch-back process may be employed to remove a portion (e.g., an upper portion) of the preliminary channel protection pattern pCPI and a portion (e.g., an upper portion) of the preliminary channel capping layer pCIP.

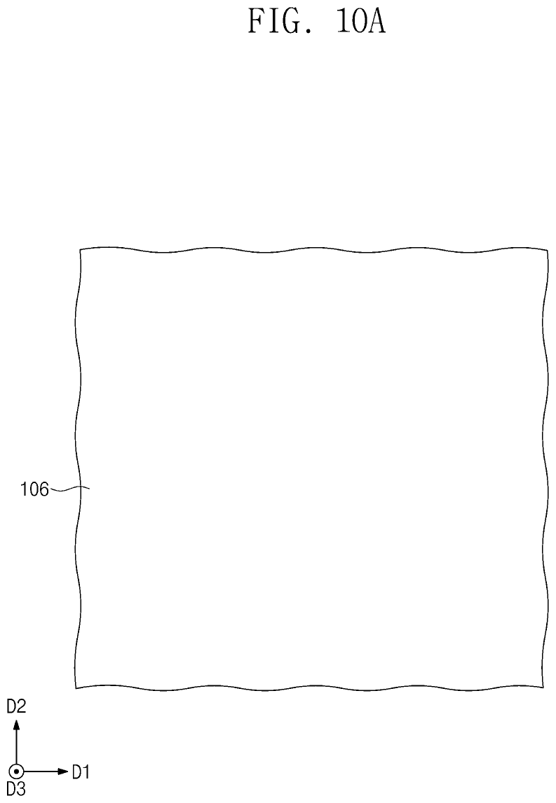

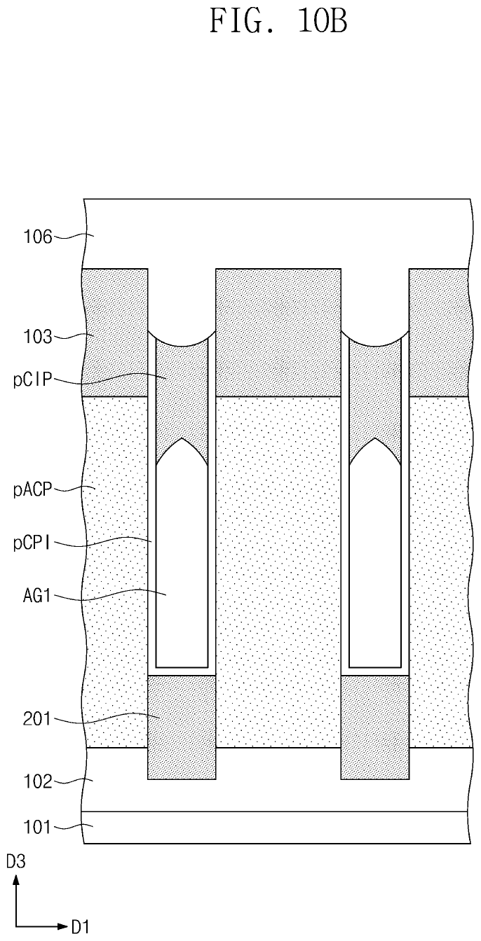

Referring to FIGS. 10A and 10B, a second sacrificial layer 106 may fill a space obtained by the partial removal of the preliminary channel protection pattern pCPI and the preliminary channel capping layer pCIP. The second sacrificial layer 106 may be on (e.g., cover or overlap) the preliminary channel protection pattern pCPI, the preliminary channel capping layer pCIP, and the first sacrificial layer 103. The second sacrificial layer 106 may include a dielectric material. For example, the second sacrificial layer 106 may include oxide.

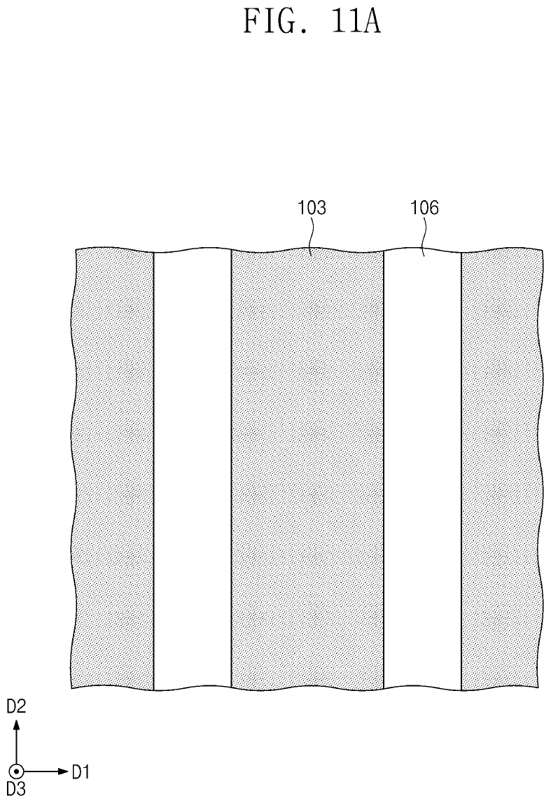

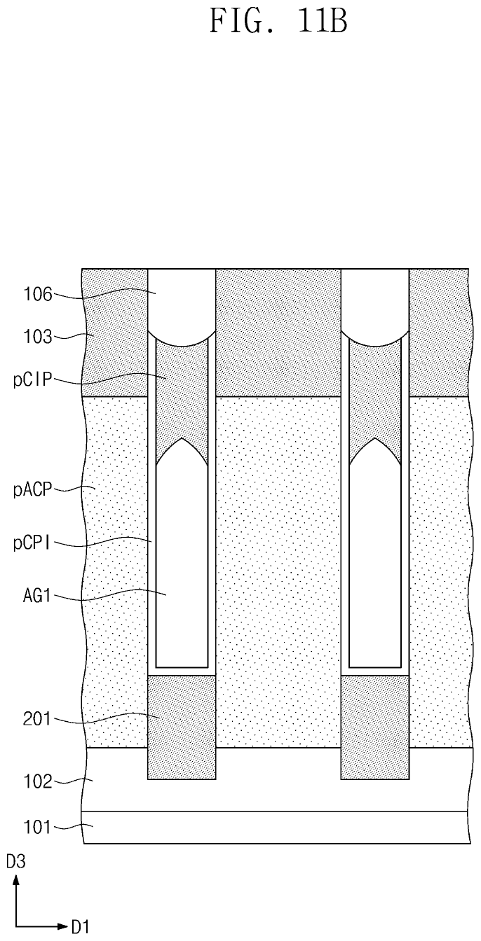

Referring to FIGS. 11A an 11B, a portion of the second sacrificial layer 106 may be removed. A portion of the second sacrificial layer 106 may be removed to expose (an upper surface of) the first sacrificial layer 103. In some embodiments, a portion of the second sacrificial layer 106 may be removed by an etch-back process.

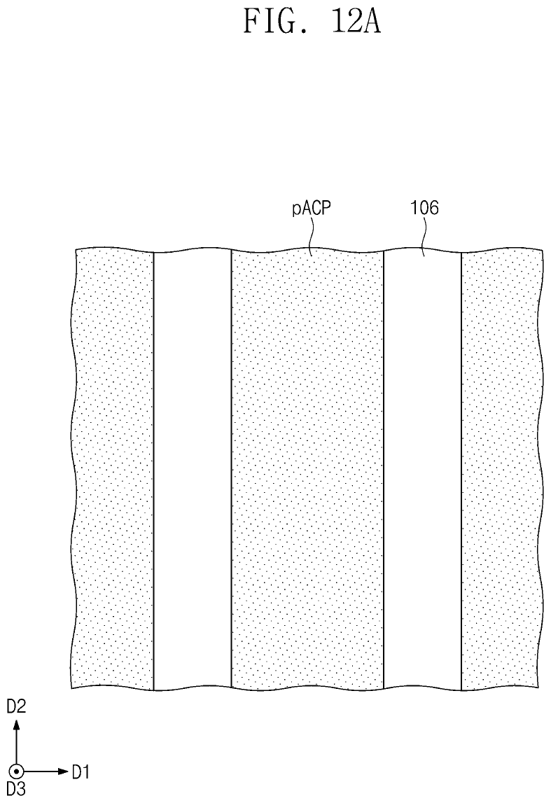

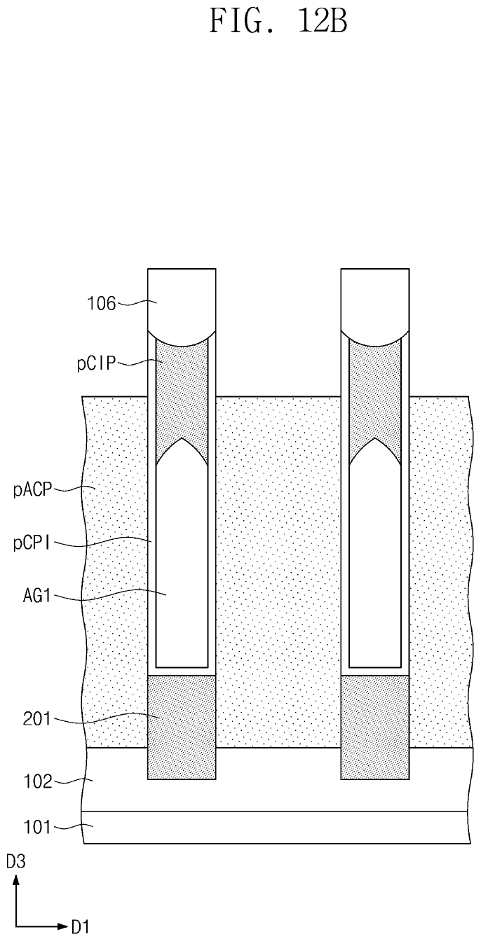

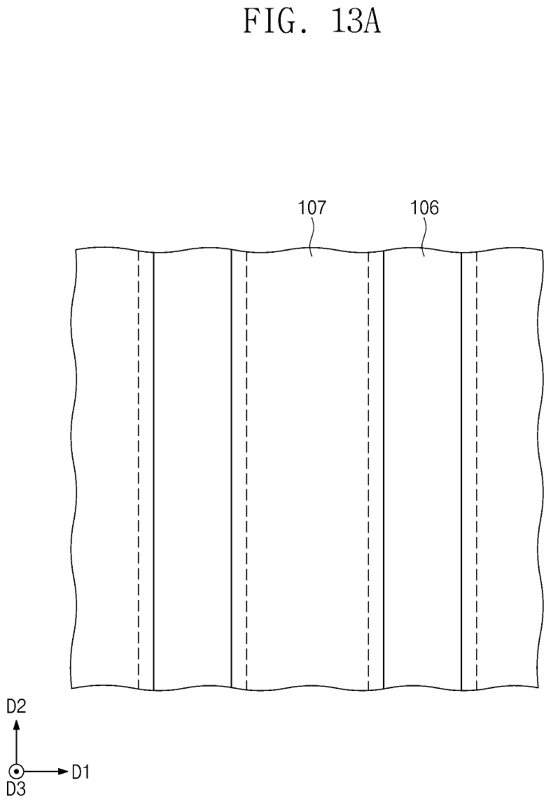

Referring to FIGS. 12A and 12B, the first sacrificial layer 103 may be removed. The first sacrificial layer 103 may be removed to expose an upper surface of the preliminary active pillar pACP and (a portion of) a sidewall of the preliminary channel protection pattern pCPI. In some embodiments, the first sacrificial layer 103 may be removed by a wet etching process.

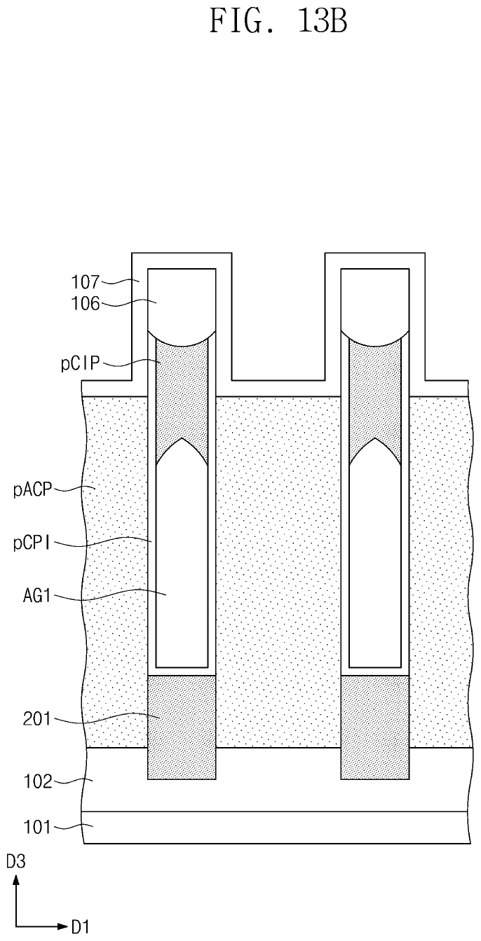

Referring to FIGS. 13A and 13B, a third sacrificial layer 107 may be formed. The third sacrificial layer 107 may be formed on (e.g., may conformally cover) the upper surface of the preliminary active pillar pACP, (the portion of) the sidewall of the preliminary channel protection pattern pCPI, and the second sacrificial layer 106.

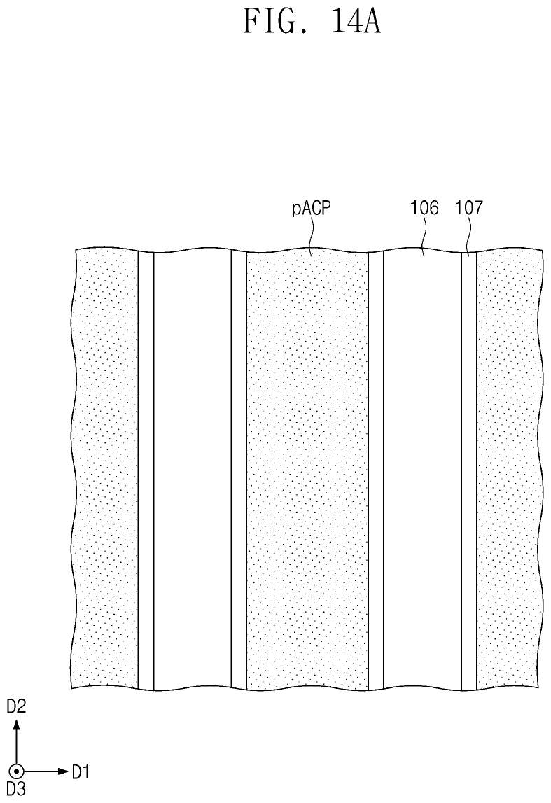

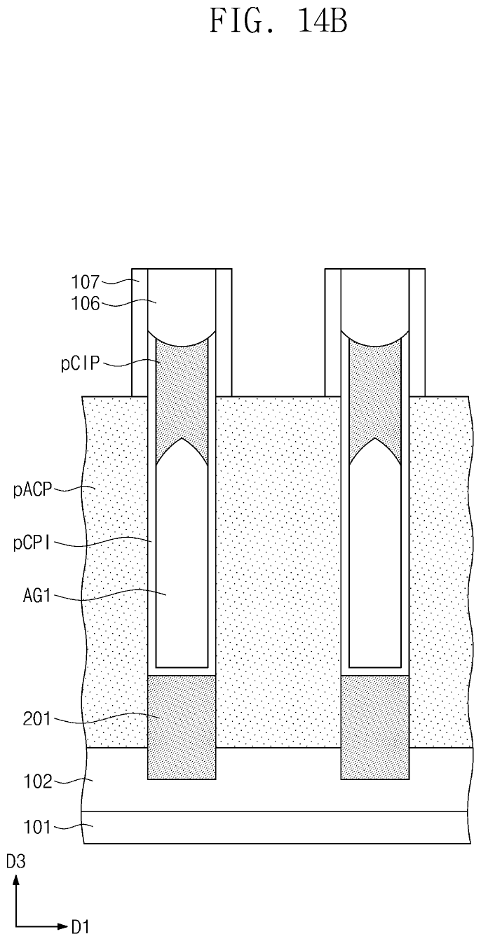

Referring to FIGS. 14A and 14B, a portion of the third sacrificial layer 107 may be etched. A portion of the third sacrificial layer 107 may be etched to expose the upper surface of the preliminary active pillar pACP and an upper surface of the second sacrificial layer 106. The third sacrificial layer 107 may remain on (the portion of) the sidewall of the preliminary channel protection pattern pCPI and a sidewall of the second sacrificial layer 106.

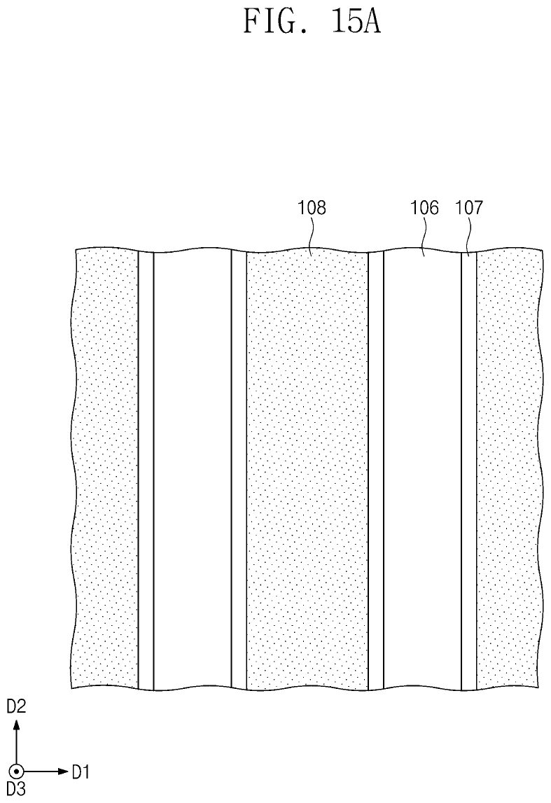

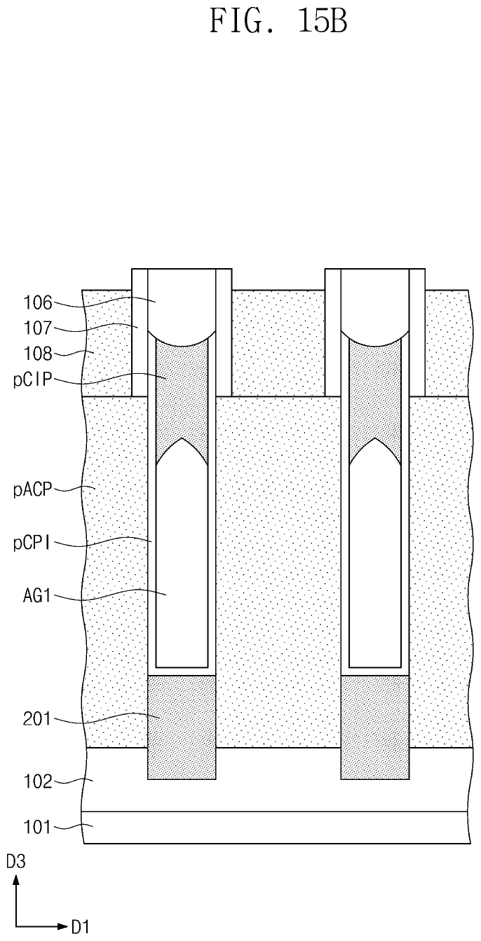

Referring to FIGS. 15A and 15B, a second mask layer 108 may be formed. The second mask layer 108 may be formed on the exposed upper surface of the preliminary active pillar pACP and a sidewall of the third sacrificial layer 107. For example, the second mask layer 108 may include polysilicon.

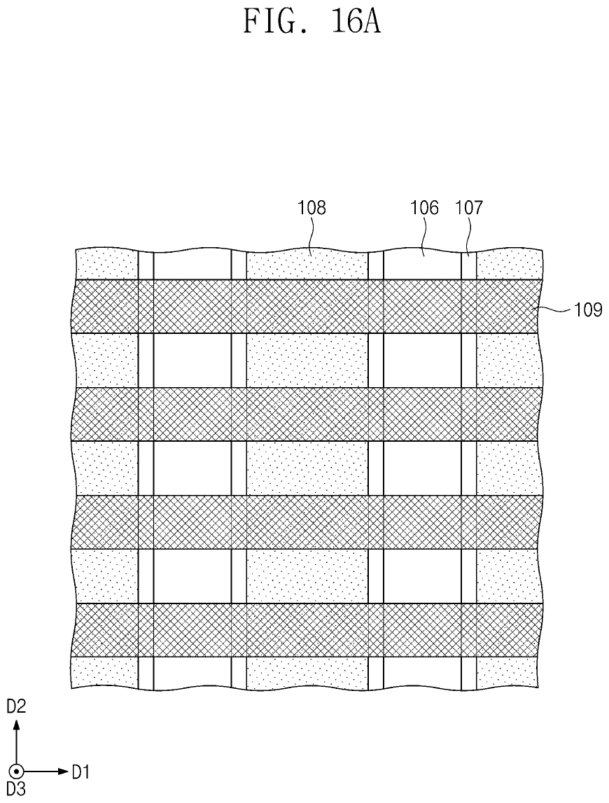

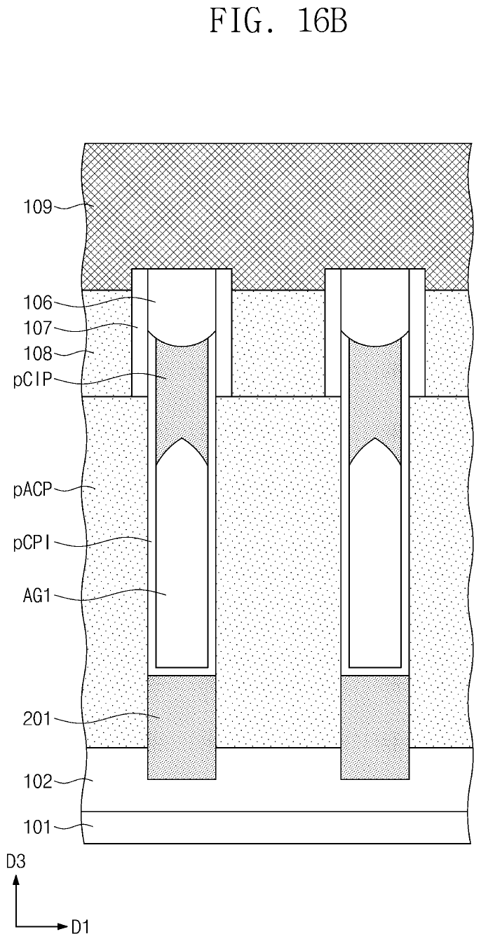

Referring to FIGS. 16A and 16B, photoresist patterns 109 may be formed on the second sacrificial layer 106, the third sacrificial layer 107, and the second mask layer 108. Each of the photoresist patterns 109 may extend in the first direction D1. The photoresist patterns 109 may be spaced apart from each other in the second direction D2. There may be exposed an upper surface of the second sacrificial layer 106, an upper surface of the third sacrificial layer 107, and an upper surface of the second mask layer 108, which upper surfaces are not covered with the photoresist pattern 109. The photoresist patterns 109 may be used to pattern the exposed upper surface of the second sacrificial layer 106, the exposed upper surface of the third sacrificial layer 107, and the exposed upper surface of the second mask layer 108.

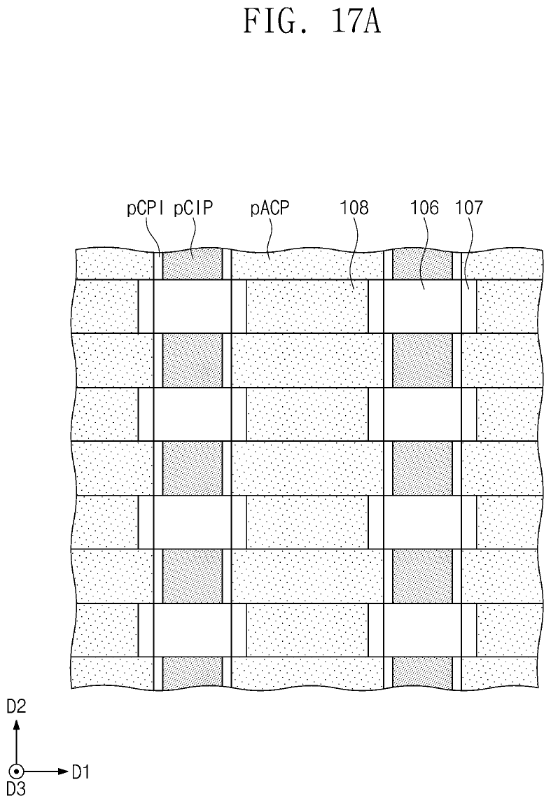

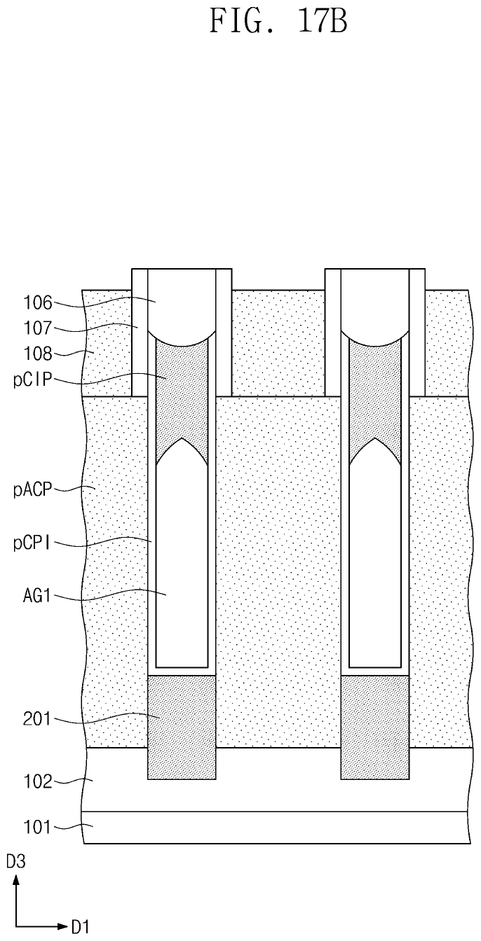

Referring to FIGS. 17A and 17B, the exposed upper surface of the second sacrificial layer 106, the exposed upper surface of the third sacrificial layer 107, and the exposed upper surface of the second mask layer 108 may be patterned to expose the upper surface of the preliminary active pillar pACP, an upper surface of the preliminary channel protection pattern pCPI, and an upper surface of the preliminary channel capping layer pCIP.

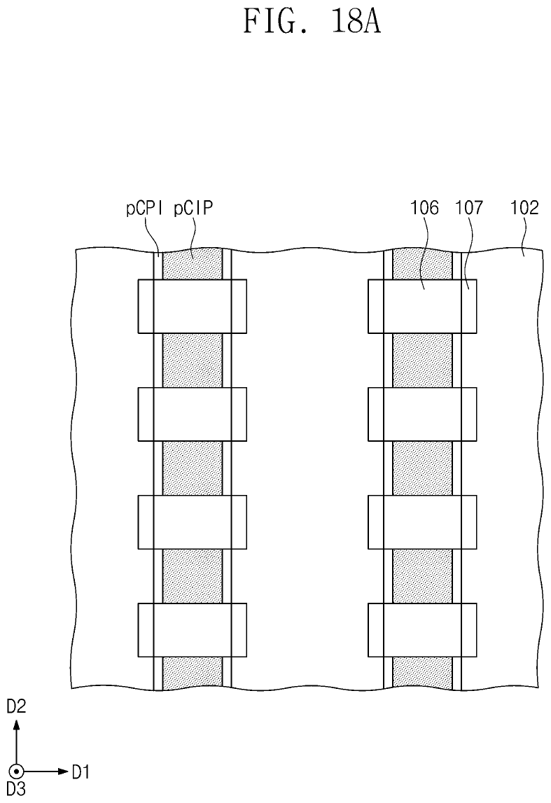

Referring to FIGS. 18A and 18B, an etching action may be performed on the preliminary active pillar pACP, the second mask layer 108, and a portion of the wafer dielectric layer 102. The second mask layer 108 may be etched and removed. The preliminary active pillar pACP and the second mask layer 108 may be etched to expose the wafer dielectric layer 102. A remaining portion of the preliminary active pillar pACP after the etching action may overlap the third sacrificial layer 107 in the third direction D3.

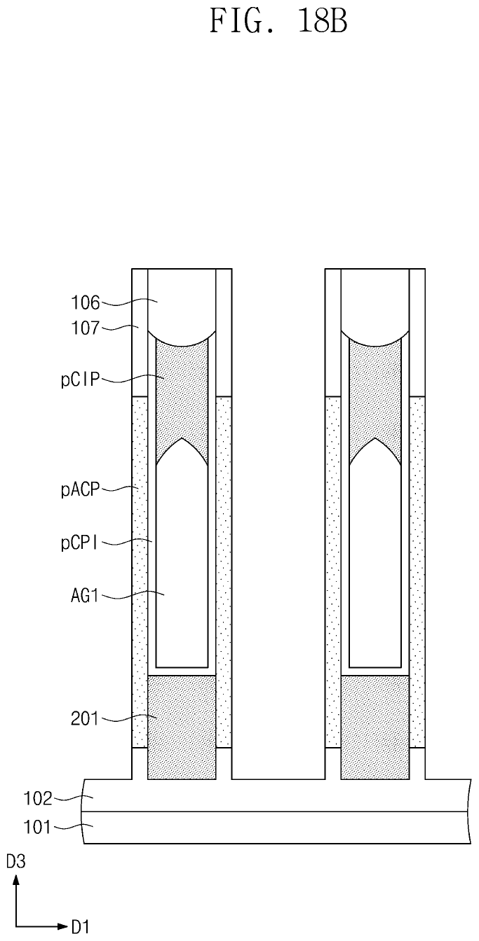

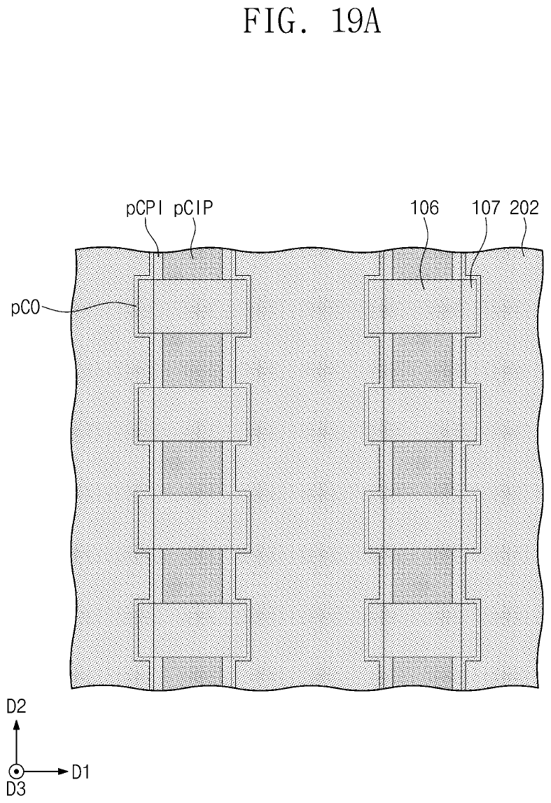

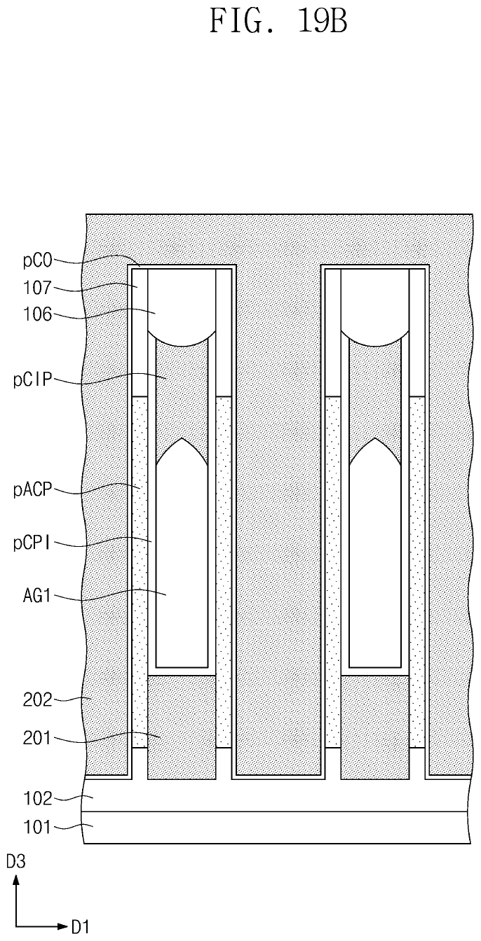

Referring to FIGS. 19A and 19B, a preliminary support dielectric layer pCO may be formed, and a second upper dielectric pattern 202 may be formed on the preliminary support dielectric layer pCO. The preliminary support dielectric layer pCO may be formed on (e.g., conformally cover or overlap) the wafer dielectric layer 102, a sidewall of the preliminary active pillar pACP, (an upper surface of) the second sacrificial layer 106, and the upper surface (and a sidewall) of the third sacrificial layer 107. The preliminary support dielectric layer pCO and the second upper dielectric pattern 202 may include a dielectric material. For example, the preliminary support dielectric layer pCO may include oxide, and the second upper dielectric pattern 202 may include nitride.

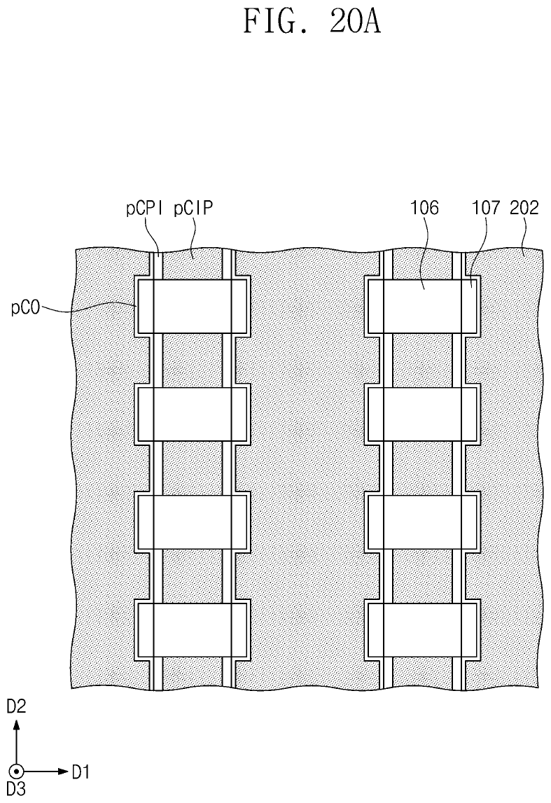

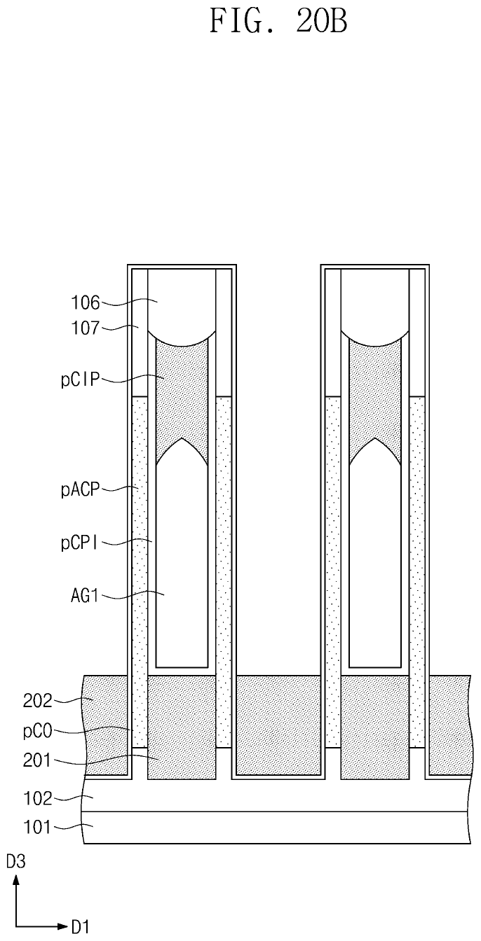

Referring to FIGS. 20A and 20B, an upper portion of the second upper dielectric pattern 202 may be removed. A lower portion of the second upper dielectric pattern 202 may not be removed. An upper surface of (the remaining portion or the lower portion of) the second upper dielectric pattern 202 that is not removed may be located at the same level (e.g., the same distance from an upper surface of the wafer substrate 101 in the third direction D3) as that of an upper surface of the first upper dielectric pattern 201. In some embodiments, a portion (e.g., the upper portion) of the second upper dielectric pattern 202 may be removed by an etch-back process.

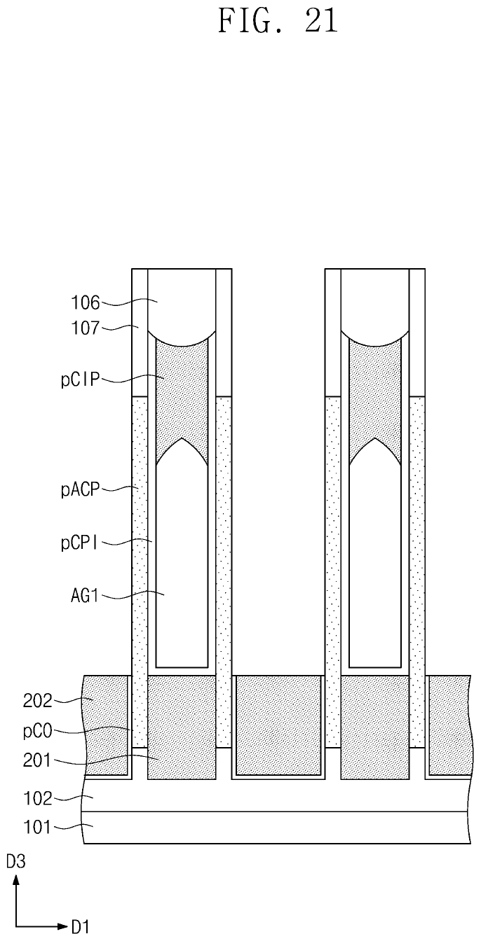

Referring to FIG. 21, a portion (e.g., an upper portion) of the preliminary support dielectric layer pCO may be removed. A portion (e.g., an upper portion) of the preliminary support dielectric layer pCO may be removed to expose the sidewall of the preliminary active pillar pACP, (the upper surface of) the second sacrificial layer 106, and (the upper surface and the sidewall of) the third sacrificial layer 107. In some embodiments, a portion (e.g., an upper portion) of the preliminary support dielectric layer pCO may be removed by a wet etching process.

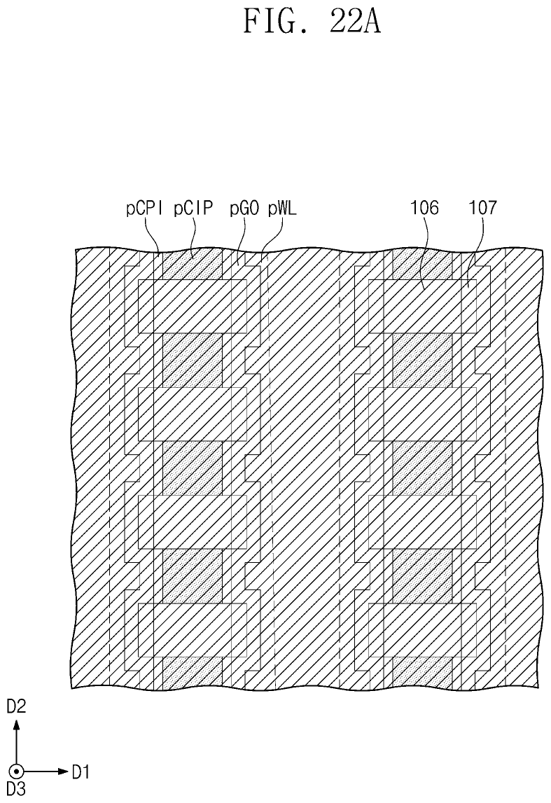

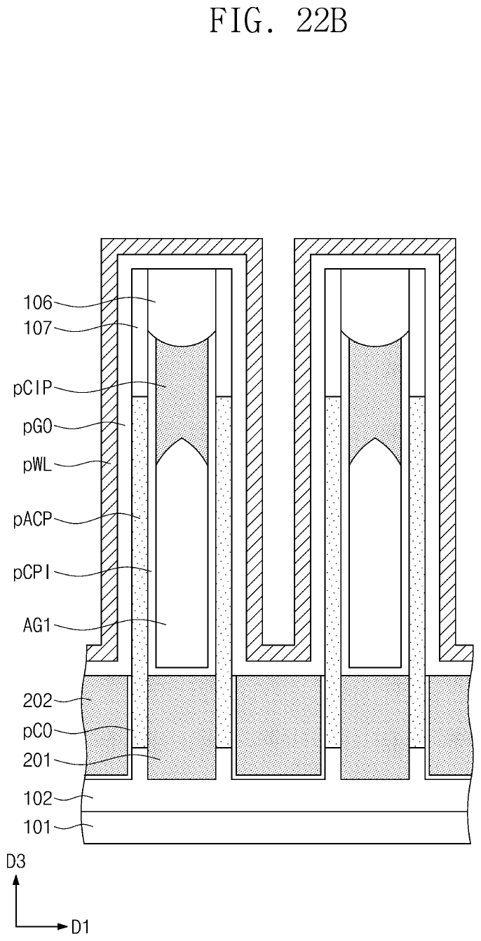

Referring to FIGS. 22A and 22B, a preliminary gate dielectric layer pGO may be formed, and a preliminary word line pWL may be formed on the preliminary gate dielectric layer pGO. The preliminary gate dielectric layer pGO may be conformally formed on (the upper surface of) the second upper dielectric pattern 202, (the upper surface of) the preliminary support dielectric layer pCO, the sidewall of the preliminary active pillar pACP, (the upper surface of) the second sacrificial layer 106, and (the upper surface and the sidewall of) the third sacrificial layer 107. The preliminary word line pWL may be conformally formed on the preliminary gate dielectric layer pGO.

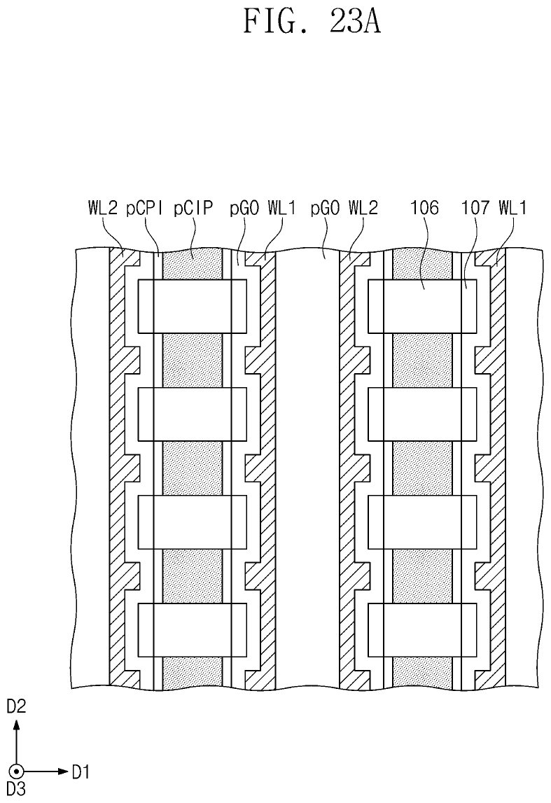

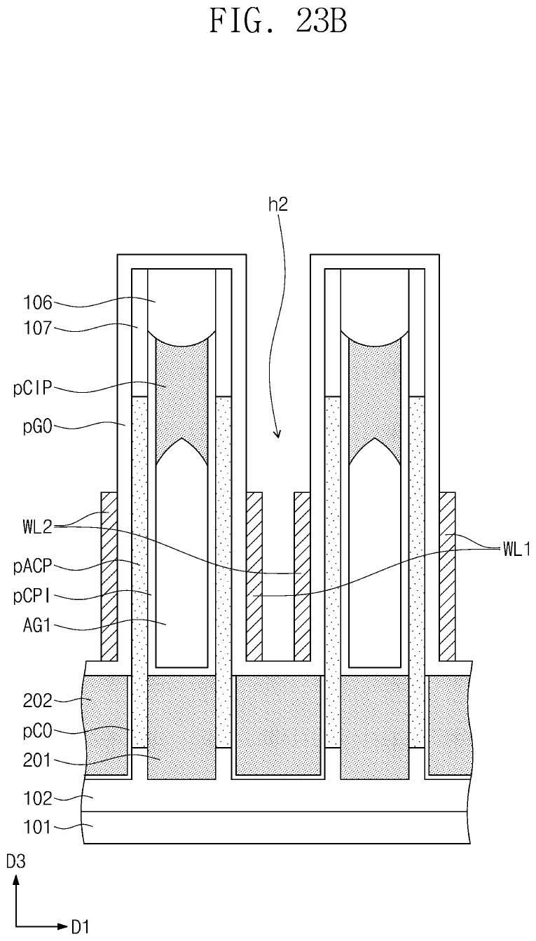

Referring to FIGS. 23A and 23B, a portion (e.g., an upper portion) of the preliminary word line pWL may be removed to form a first word line WL1 and a second word line WL2. A space h2 may be formed in (defined by) the first word line WL1, the second word line WL2, and the preliminary gate dielectric layer pGO. The space h2 in the first word line WL1, the second word line WL2, and the preliminary gate dielectric layer pGO may be defined by surfaces (e.g., sidewalls) of the preliminary gate dielectric layer pGO and surfaces (e.g., sidewalls) of the first and second word lines WL1 and WL2 in the preliminary gate dielectric layer pGO. For example, the space h2 may be defined between sidewalls of the preliminary gate dielectric layer pGO facing each other and between a sidewall of the first word line WL1 and a sidewall of the second word line WL2 facing each other. In some embodiments, a portion of the preliminary word line pWL may be removed by an etch-back process.

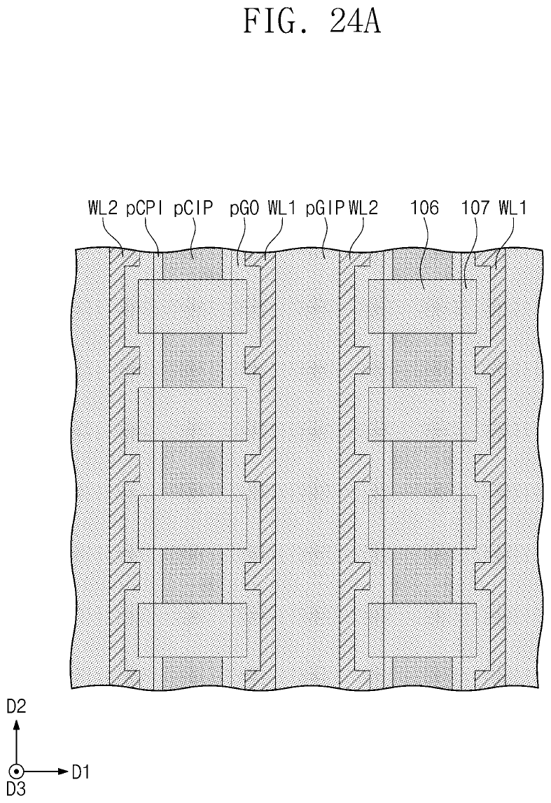

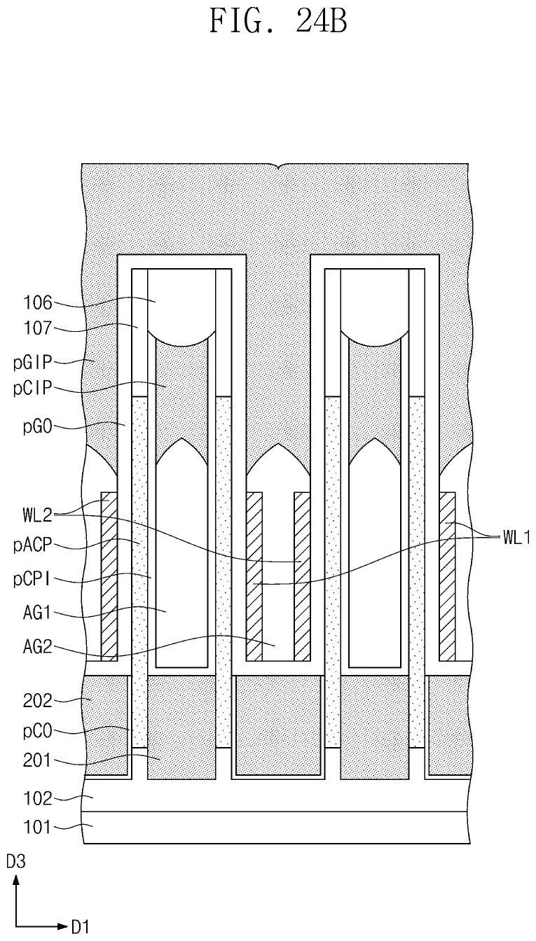

Referring to FIGS. 24A and 24B, a preliminary gate capping layer pGIP may be formed on the preliminary gate dielectric layer pGO. The preliminary gate capping layer pGIP may partially fill the space h2. For example, the preliminary gate capping layer pGIP may (partially) fill an upper portion of the space h2 between the facing sidewalls of the preliminary gate dielectric layer pGO. The preliminary gate capping layer pGIP may not fill a lower portion of the space h2 between the sidewall of the first word line WL1 and the sidewall of the second word line WL2 facing each other. The preliminary gate capping layer pGIP may not be formed on any of the first and second word lines WL1 and WL2. A gate air gap AG2 may be defined to indicate the lower portion of the space h2 between (sidewalls of) the preliminary gate dielectric layer pGO. The gate air gap AG2 may be surrounded (e.g., enclosed) by the preliminary gate dielectric layer pGO, the preliminary gate capping layer pGIP, the first word line WL1, and the second word line WL2. The preliminary gate capping layer pGIP may include a dielectric material.

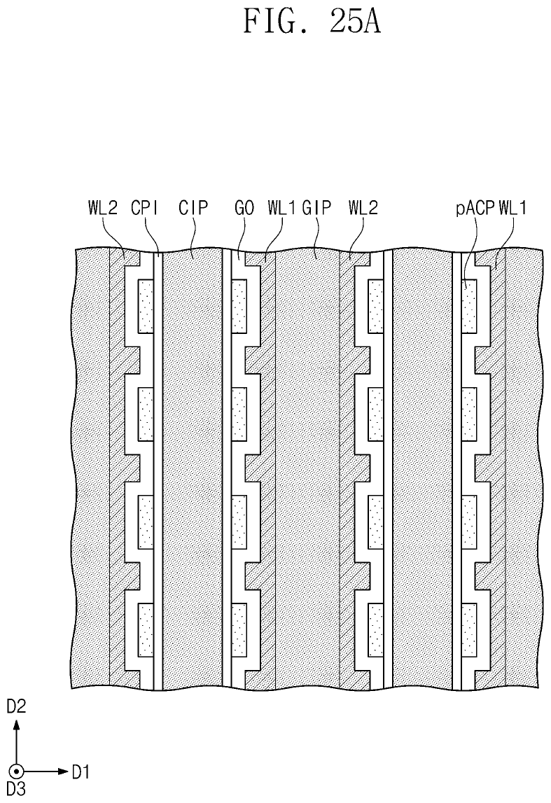

Referring to FIGS. 25A and 25B, there may be removed a portion (e.g., an upper portion) of the preliminary gate capping layer pGIP, a portion (e.g., an upper portion) of the preliminary gate dielectric layer pGO, the second sacrificial layer 106, the third sacrificial layer 107, a portion (e.g., an upper portion) of the preliminary channel protection pattern pCPI, and a portion (e.g., an upper portion) of the preliminary channel capping layer pCIP. The preliminary gate capping layer pGIP, the preliminary gate dielectric layer pGO, the preliminary channel protection pattern pCPI, and the preliminary channel capping layer pCIP may be partially removed to form a gate capping layer GIP, a gate dielectric layer GO, a channel protection pattern CPI, and a channel capping layer CIP, respectively. In some embodiments, a chemical mechanical polishing process may be performed to remove a portion (e.g., an upper portion) of the preliminary gate capping layer pGIP, a portion (e.g., an upper portion) of the preliminary gate dielectric layer pGO, the second sacrificial layer 106, the third sacrificial layer 107, a portion (e.g., an upper portion) of the preliminary channel protection pattern pCPI, and a portion (e.g., an upper portion) of the preliminary channel capping layer pCIP.

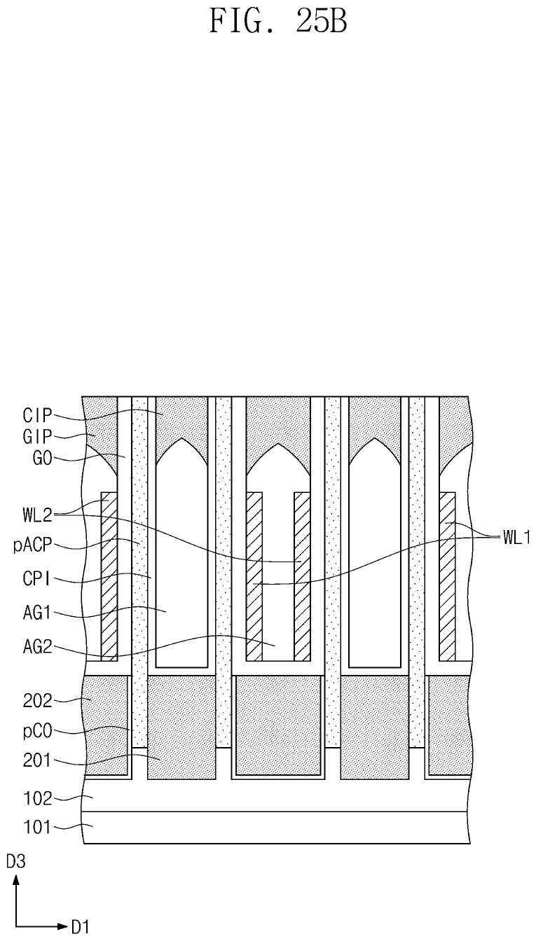

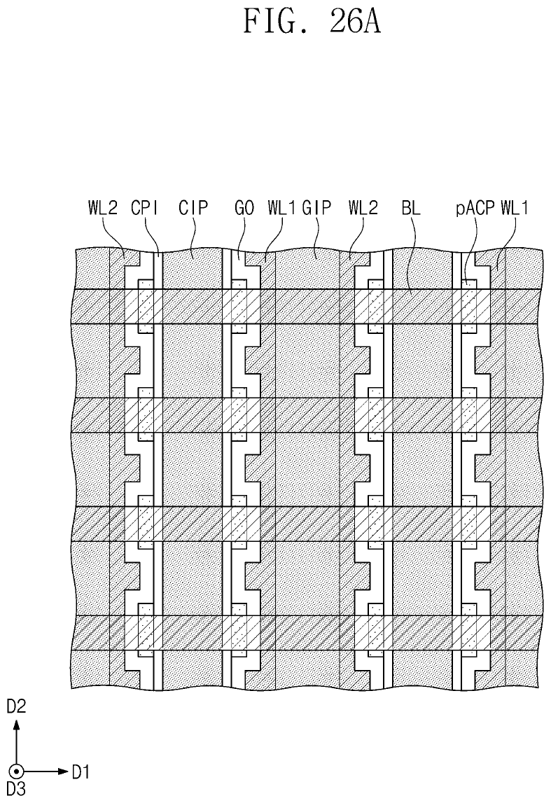

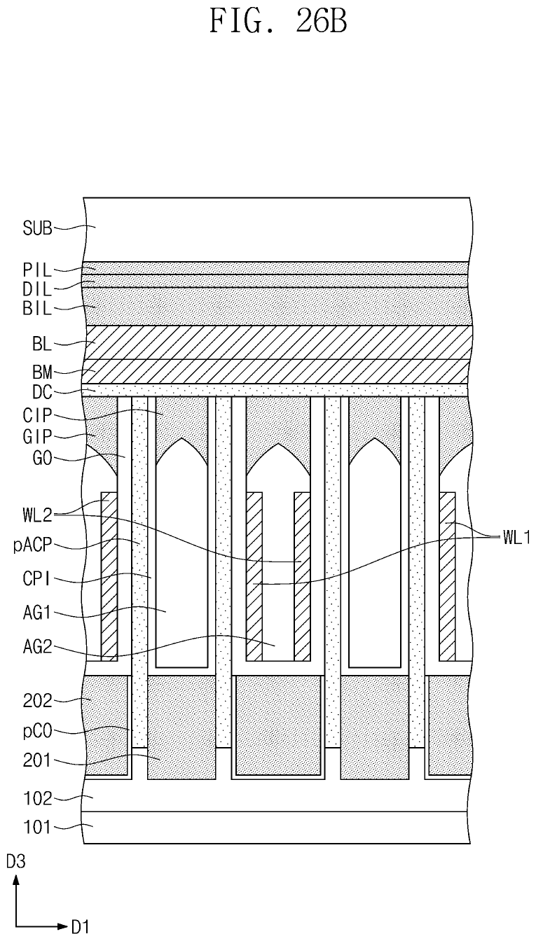

Referring to FIGS. 26A and 26B, a connection layer DC may be formed on the preliminary active pillar pACP, the gate capping layer GIP, the gate dielectric layer GO, the channel protection pattern CPI, and the channel capping layer CIP. There may be formed a barrier layer BM on the connection layer DC, a bit line BL on the barrier layer BM, and a bit-line dielectric layer BIL on the bit line BL. A substrate SUB may be formed, and a peripheral circuit dielectric layer PIL may be formed on the substrate SUB. The substrate SUB and the peripheral circuit dielectric layer PIL may be interchangeable. The peripheral circuit dielectric layer PIL may be bonded to the bit-line dielectric layer BIL. The peripheral circuit dielectric layer PIL and the bit-line dielectric layer BIL may be bonded to each other by a wafer bonding process. In some embodiments, a lower dielectric layer DIL may be formed on the bit-line dielectric layer BIL. The lower dielectric layer DIL may be between the bit-line dielectric layer BIL and the peripheral circuit dielectric layer PIL. The lower dielectric layer DIL may be bonded to the peripheral circuit dielectric layer PIL by a wafer bonding process.

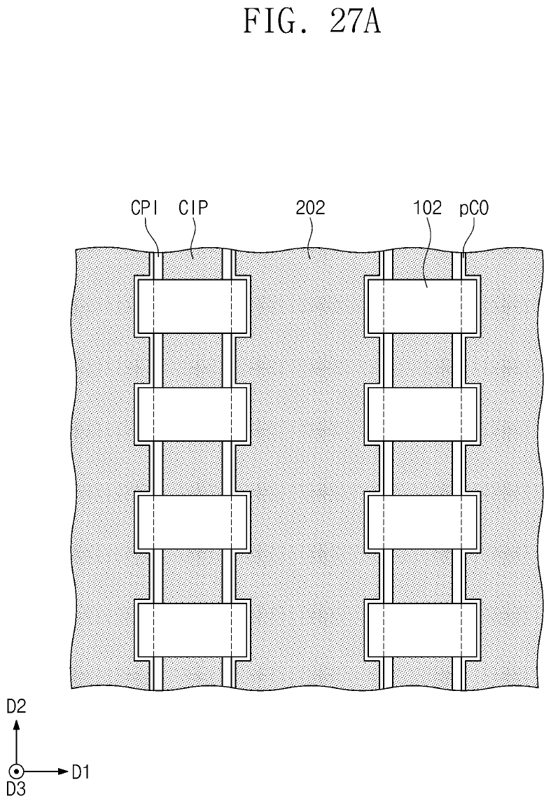

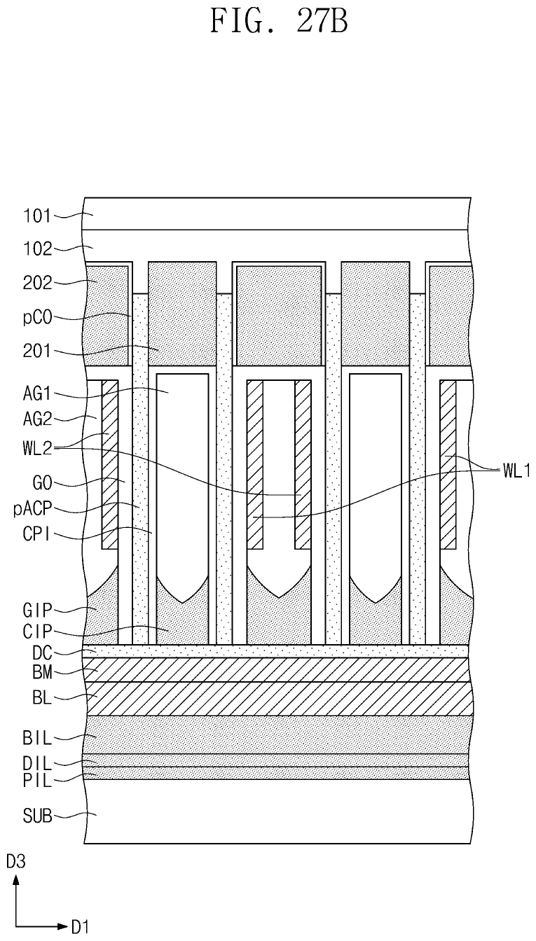

Referring to FIGS. 27A and 27B, a semiconductor device may be turned upside down. The substrate SUB may be positioned at a lower portion of the semiconductor device. The wafer substrate 101 may be positioned at an upper portion of the semiconductor device.

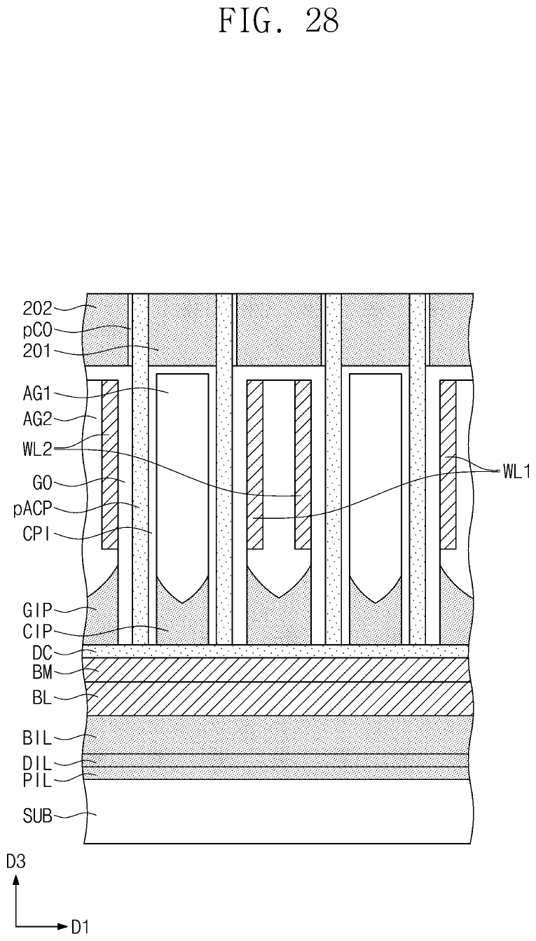

Referring to FIG. 28, there may be removed the wafer substrate 101, the wafer dielectric layer 102, a portion (e.g., an upper portion) of the preliminary support dielectric layer pCO, a portion (e.g., an upper portion) of the first upper dielectric pattern 201, and a portion (e.g., an upper portion) of the second upper dielectric pattern 202. The wafer substrate 101, the wafer dielectric layer 102, a portion (e.g., an upper portion) of the preliminary support dielectric layer pCO, a portion (e.g., an upper portion) of the first upper dielectric pattern 201, and a portion (e.g., an upper portion) of the second upper dielectric pattern 202 may be removed to expose an upper surface of the preliminary support dielectric layer pCO, an upper surface of the first upper dielectric pattern 201, an upper surface of the second upper dielectric pattern 202, and the upper surface of the preliminary active pillar pACP. In some embodiments, a chemical mechanical polishing process may be used to remove the wafer substrate 101, the wafer dielectric layer 102, a portion (e.g., an upper portion) of the preliminary support dielectric layer pCO, a portion (e.g., an upper portion) of the first upper dielectric pattern 201, and a portion (e.g., an upper portion) of the second upper dielectric pattern 202.

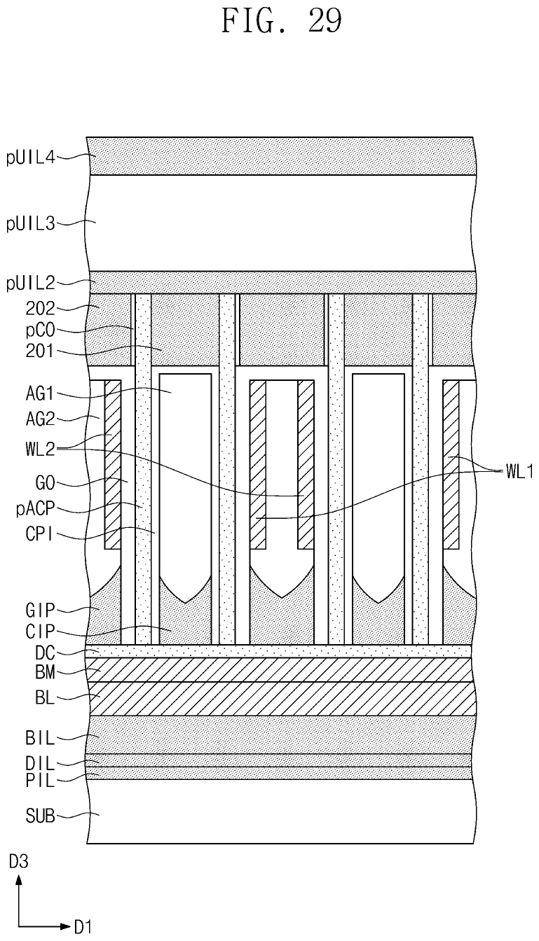

Referring to FIG. 29, a second preliminary upper dielectric layer pUIL2 may be formed on the upper surface of the preliminary support dielectric layer pCO, the upper surface of the first upper dielectric pattern 201, the upper surface of the second upper dielectric pattern 202, and the upper surface of the preliminary active pillar pACP. A third preliminary upper dielectric layer pUIL3 may be formed on the second preliminary upper dielectric layer pUIL2, and a fourth preliminary upper dielectric layer pUIL4 may be formed on the third preliminary upper dielectric layer pUIL3.

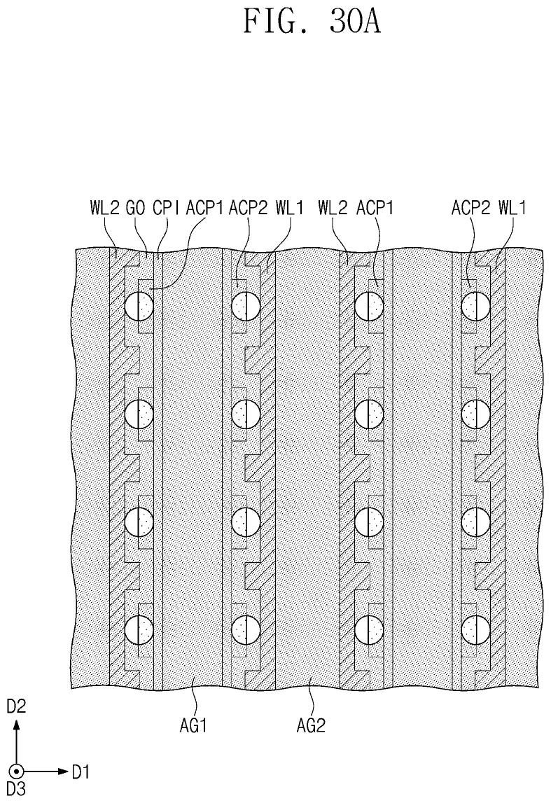

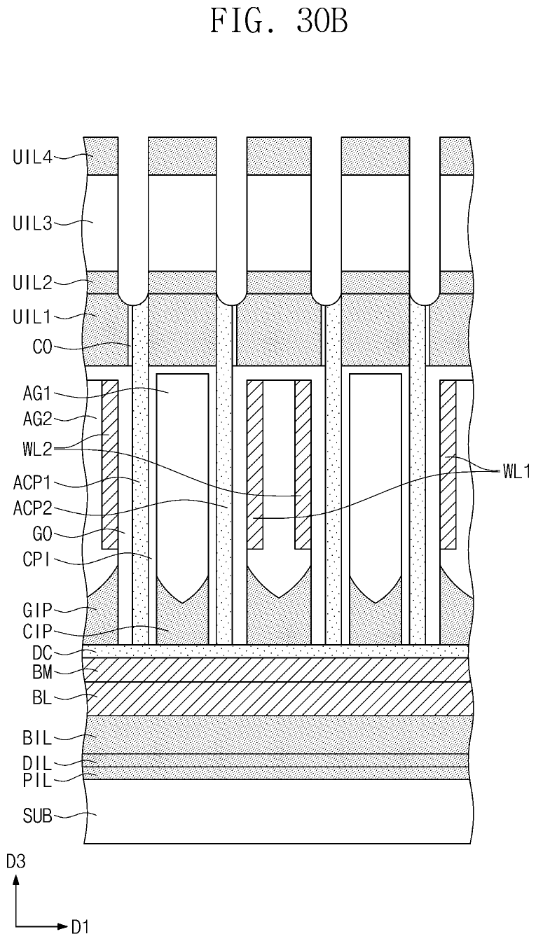

Referring to FIGS. 30A and 30B, there may be removed an upper portion of the preliminary active pillar pACP, an upper portion of the preliminary support dielectric layer pCO, a portion of the second upper dielectric pattern 202, a portion of the second preliminary upper dielectric layer pUIL2, a portion of the third preliminary upper dielectric layer pUIL3, and a portion of the fourth preliminary upper dielectric layer pUIL4. An upper portion of the preliminary active pillar pACP may be removed to form an active pillar ACP1 or ACP2. An upper portion of the preliminary support dielectric layer pCO may be removed to form a support dielectric layer CO. The first upper dielectric pattern 201 and the partially removed second upper dielectric pattern 202 may be defined as a first upper dielectric layer UIL1. The second, third, and fourth preliminary upper dielectric layers pUIL2, pUIL3, and pUIL4 may be partially removed to form second, third, and fourth upper dielectric layers UIL2, UIL3, and UIL4.

Referring to FIGS. 2A and 2B, data contacts BC may be formed, and first, second, and third landing pads LP1, LP2, and LP3 may be formed. The data contact BC may fill a space formed by the removal of an upper portion of the preliminary active pillar pACP, an upper portion of the preliminary support dielectric layer pCO, a portion of the second upper dielectric pattern 202, a portion of the second preliminary upper dielectric layer pUIL2, and a portion of the third preliminary upper dielectric layer pUIL3. The first, second, and third landing pads LP1, LP2, and LP3 may fill a space formed by the partial removal of the third preliminary upper dielectric layer pUIL3 and the fourth preliminary upper dielectric layer pUIL4. Data storage patterns DSP may be formed to be correspondingly connected (e.g., electrically connected) with the landing pads LP1, LP2, and LP3.

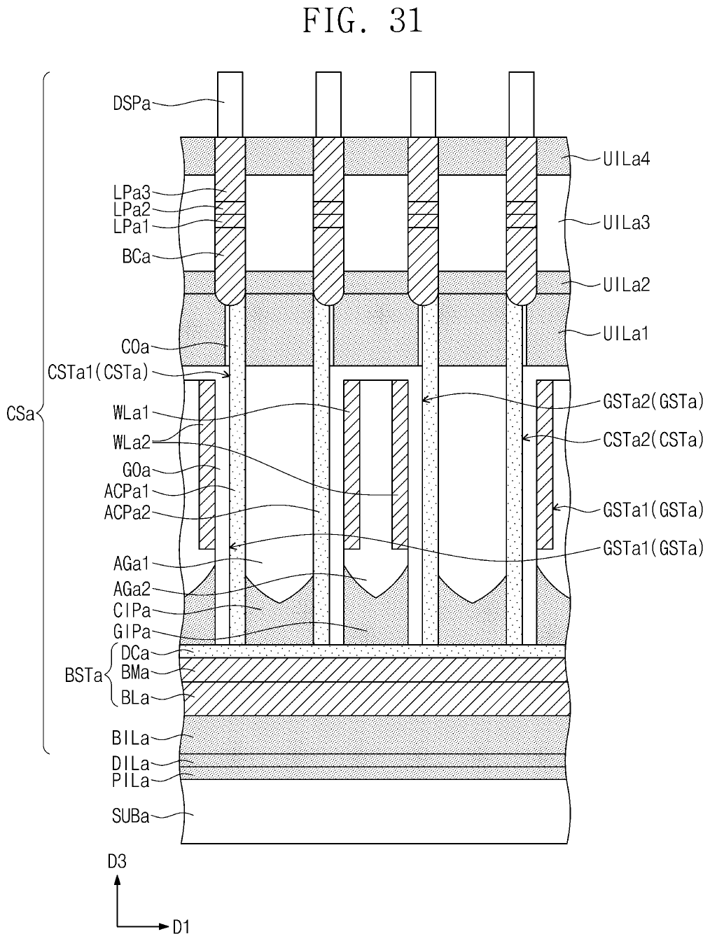

FIG. 31 illustrates a cross-sectional view showing a semiconductor device according to some embodiments.

Referring to FIG. 31, in a semiconductor device, a channel air gap AGa1 may be (defined) between a first active pillar ACPa1 and a second active pillar ACPa2. An upper surface of the channel air gap AGa1 may be defined by a lower surface of a first upper dielectric layer UILa1. For example, the lower surface of the first upper dielectric layer UILa1 may be exposed to the channel air gap AGa1. The channel air gap AGa1 may have sidewalls defined by inner sidewalls of the first and second active pillars ACPa1 and ACPa2. For example, the inner sidewalls of the first and second active pillars ACPa1 and ACPa2 may be exposed to the channel air gap AGa1. A channel capping layer CIPa may be in contact with the first and second active pillars ACPa1 and ACPa2. A lower surface of the channel air gap AGa1 may be defined by an upper surface of the channel capping layer CIPa. For example, the upper surface of the channel capping layer CIPa may be exposed to the channel air gap AGa1.

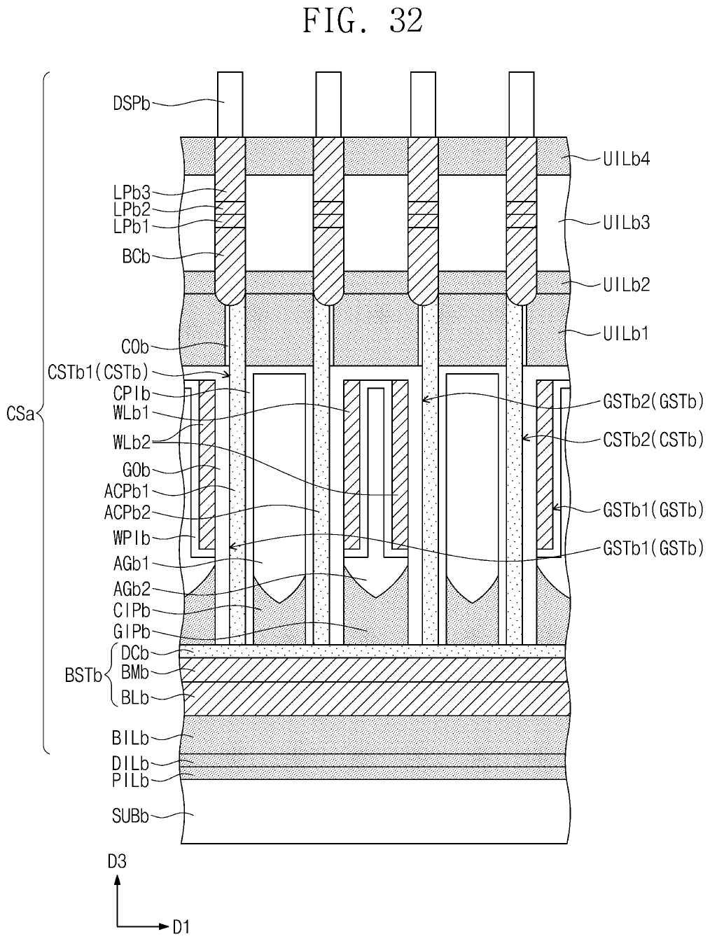

FIG. 32 illustrates a cross-sectional view showing a semiconductor device according to some embodiments.

Referring to FIG. 32, a gate structure GSTb may further include a word-line protection pattern WPIb in contact with a first word line WLb1, a second word line WLb2, and a gate dielectric layer GOb. The word-line protection pattern WPIb may be disposed in the gate dielectric layer GOb. The word-line protection pattern WPIb may cover inner sidewalls and bottom surfaces of the first and second word lines WLb1 and WLb2. A gate air gap AGb2 may be defined by the word-line protection pattern WPIb and a gate capping layer GIPb. A gate air gap AGb2 may be defined by the word-line protection pattern WPIb, the gate dielectric layer GOb, and the gate capping layer GIPb.

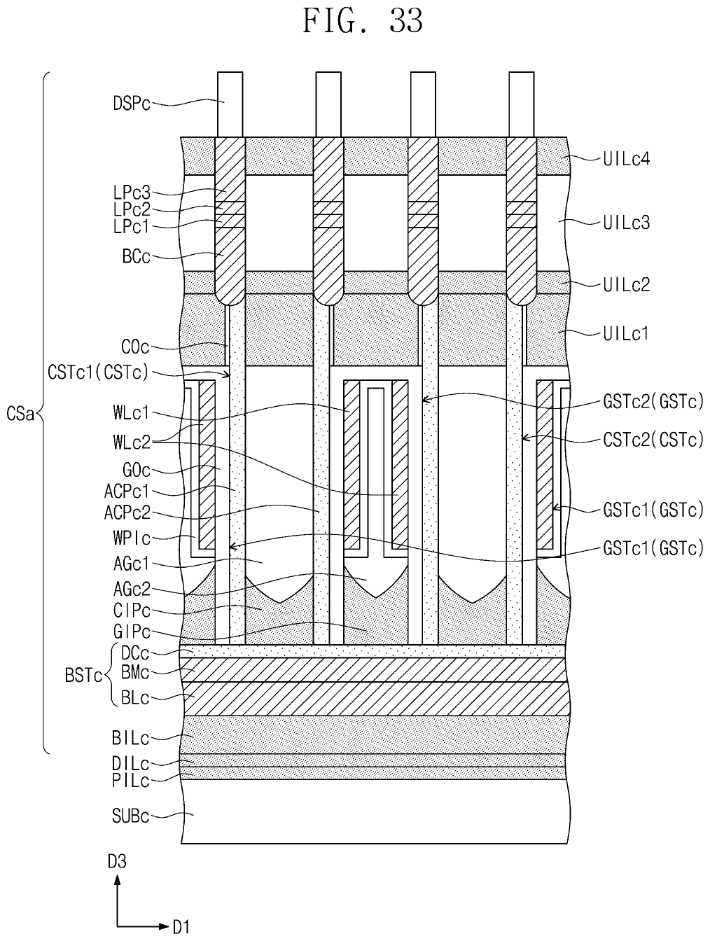

FIG. 33 illustrates a cross-sectional view showing a semiconductor device according to some embodiments.

Referring to FIG. 33, in a semiconductor device, a channel air gap AGc1 may be (defined) between a first active pillar ACPc1 and a second active pillar ACPc2. An upper surface of the channel air gap AGc1 may be defined by a lower surface of a first upper dielectric layer UILc1. For example, the lower surface of the first upper dielectric layer UILc1 may be exposed to the channel air gap AGc1. The channel air gap AGc1 may have sidewalls defined by inner sidewalls of the first and second active pillars ACPc1 and ACPc2. For example, the inner sidewalls of the first and second active pillars ACPc1 and ACPc2 may be exposed to the channel air gap AGc1. A channel capping layer CIPc may be in contact with the first and second active pillars ACPc1 and ACPc2. A lower surface of the channel air gap AGc1 may be defined by an upper surface of the channel capping layer CIPc. For example, the upper surface of the channel capping layer CIPc may be exposed to the channel air gap AGc1.

A gate structure GSTc may further include a word-line protection pattern WPIc in contact with a first word line WLc1, a second word line WLc2, and a gate dielectric layer GOc. The word-line protection pattern WPIc may be disposed in the gate dielectric layer GOc. The word-line protection pattern WPIc may be on (e.g., cover) inner sidewalls and lower surfaces of the first and second word lines WLc1 and WLc2. A gate air gap AGc2 may be defined by the word-line protection pattern WPIc and a gate capping layer GIPc. For example, each of the word-line protection pattern WPIc and the gate capping layer GIPc may include a portion that is exposed to the gate air gap AGc2. A gate air gap AGc2 may be defined by the word-line protection pattern WPIc, the gate dielectric layer GOc, and the gate capping layer GIPc. For example, each of the word-line protection pattern WPIc, the gate dielectric layer GOc, and the gate capping layer GIPc may include a portion that is exposed to the gate air gap AGc2. For example, a lower surface and an inner sidewall of the word-line protection pattern WPIc, a sidewall of the gate dielectric layer GOc, and/or an upper surface of the gate capping layer GIPc may be exposed to the gate air gap AGc2.

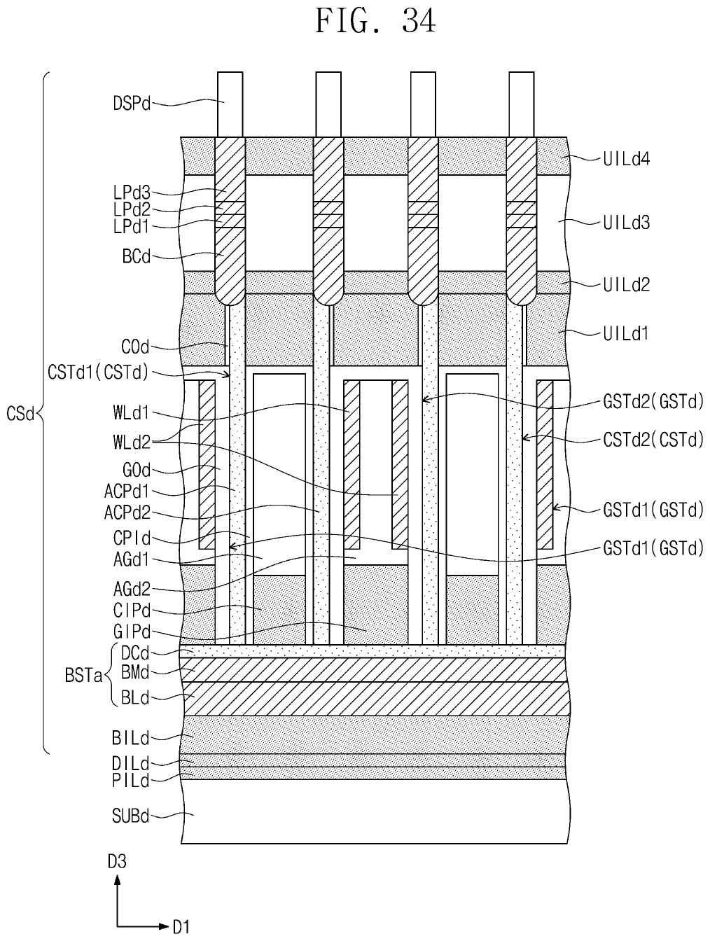

FIG. 34 illustrates a cross-sectional view showing a semiconductor device according to some embodiments.

Referring to FIG. 34, in a semiconductor device, a channel air gap AGd1 may be defined by a channel protection pattern CPId and a channel capping layer CIPd. A lower surface of the channel air gap AGd1 may be defined by an upper surface of the channel capping layer CIPd. For example, the upper surface of the channel capping layer CIPd may be exposed to the channel capping layer CIPd. The upper surface of the channel capping layer CIPd may be flat. The lower surface of the channel air gap AGd1 may be flat.

A gate air gap AGd2 may be defined by a first word line WLd1, a second word line WLd2, a gate dielectric layer GOd, and a gate capping layer GIPd. Sidewalls of the first and second word lines WLd1 and WLd2 may be exposed to the gate air gap AGd2. At least a portion of a sidewall of the gate dielectric layer GOd, may be exposed to the gate air gap AGd2. A lower surface of the gate air gap AGd2 may be defined by an upper surface of the gate capping layer GIPd. For example, the upper surface of the gate capping layer GIPd may be exposed to the gate air gap AGd2. The upper surface of the gate capping layer GIPd may be flat. The lower surface of the gate air gap AGd2 may be flat.

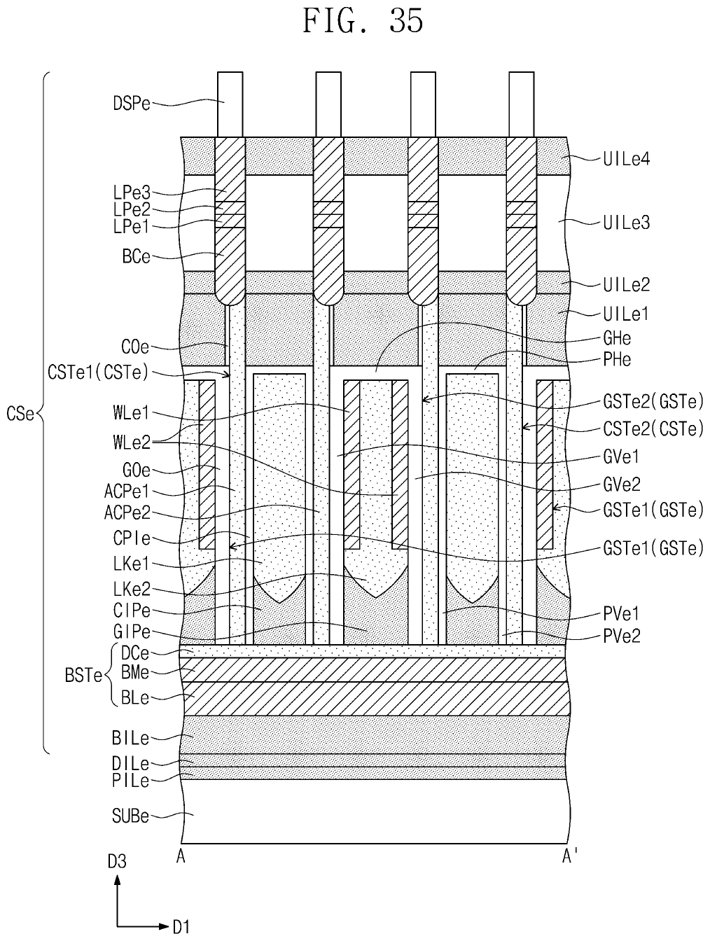

FIG. 35 illustrates a cross-sectional view showing a semiconductor device according to some embodiments.

Referring to FIG. 35, in a semiconductor device, a channel low-k material layer LKe1 may be provided on a channel capping layer CIPe. An upper surface and sidewalls of the channel low-k material layer LKe1 may be in contact with a channel protection pattern CPIe. A lower surface the channel low-k material layer LKe1 may be in contact with the channel capping layer CIPe. The channel low-k material layer LKe1 may be disposed between first and second vertical parts PVe1 and PVe2 of the channel protection pattern CPIe (in the first direction D1). The channel low-k material layer LKe1 may be disposed between the horizontal part PHe of the channel protection pattern CPIe and the channel capping layer CIPe (in the third direction D3).

A gate low-k material layer LKe2 may be provided on a gate capping layer GIPe. The gate low-k material layer LKe2 may be in contact with a first word line WLe1, a second word line WLe2, a gate dielectric layer GOe, and the gate capping layer GIPe. The gate low-k material layer LKe2 may be disposed between first and second vertical parts GVe1 and GVe2 of the gate dielectric layer GOe (in the first direction D1). The gate low-k material layer LKe2 may be disposed between the horizontal part GHe of the gate dielectric layer GOe and the gate capping layer GIPe (in the third direction D3).

A semiconductor device according to some embodiments of the present inventive concepts may include an air gap between word lines and an air gap between active pillars, and thus interference between the word lines and between the active pillars may be reduced to improve electrical properties.

Although the present invention has been described in connection with the some embodiments of the present inventive concepts illustrated in the accompanying drawings, it will be understood by one of ordinary skill in the art that variations in form and detail may be made therein without departing from the scope of the present inventive concepts. The above disclosed embodiments should thus be considered illustrative and not restrictive.

What is claimed is:

1. A semiconductor device, comprising:
a first gate structure and a second gate structure that are adjacent to each other in a first direction;
a first active pillar and a second active pillar between the first gate structure and the second gate structure;
a channel capping layer between the first active pillar and the second active pillar; and
a bit-line structure that is in contact with the first active pillar, the second active pillar, and the channel capping layer,
wherein each of the first and second gate structures includes:
a first word line and a second word line that are spaced apart from each other in the first direction;
a gate dielectric layer that is in contact with the first word line and the second word line; and
a gate capping layer that is in contact with the gate dielectric layer and spaced apart from the first word line and the second word line in a second direction that is perpendicular to the first direction, and
wherein the gate capping layer is in contact with the bit-line structure.

2. The semiconductor device of claim 1, further comprising:
a channel protection pattern that is in contact with the first active pillar, the second active pillar, and the channel capping layer.

3. The semiconductor device of claim 2, wherein the channel protection pattern includes:
a first vertical part that includes an outer sidewall in contact with the first active pillar;
a second vertical part that includes an outer sidewall in contact with the second active pillar; and
a horizontal part that connects the first vertical part and the second vertical part to each other.

4. The semiconductor device of claim 3, further comprising:
a channel air gap that is between the channel protection pattern and the channel capping layer,
wherein an inner sidewall of the first vertical part of the channel protection pattern and an inner sidewall of the second vertical part of the channel protection pattern are adjacent the channel air gap, and
wherein a lower surface of the horizontal part of the channel protection pattern is adjacent the channel air gap.

5. The semiconductor device of claim 4, wherein an upper surface of the channel capping layer is adjacent the channel air gap.

6. The semiconductor device of claim 3, further comprising:
a channel low-k material layer on the channel capping layer,
wherein the channel low-k material layer is between the first and second vertical parts of the channel protection pattern.

7. The semiconductor device of claim 1, further comprising:
a channel air gap that is adjacent an inner sidewall of the first active pillar, an inner sidewall of the second active pillar, and an upper surface of the channel capping layer, and
wherein the channel capping layer is in contact with the first and second active pillars.

8. The semiconductor device of claim 1, wherein the gate dielectric layer includes:
a first vertical part that is in contact with an outer sidewall of the first word line;
a second vertical part that is in contact with an outer sidewall of the second word line; and
a horizontal part that physically connects the first vertical part and the second vertical part to each other.

9. The semiconductor device of claim 8, further comprising:
a gate air gap that is adjacent the first and second vertical parts of the gate dielectric layer, the horizontal part of the gate dielectric layer, the first word line, the second word line, and the gate capping layer,
wherein the gate air gap overlaps the gate capping layer in the second direction.

10. The semiconductor device of claim 9, wherein an inner sidewall of the first word line and an inner sidewall of the second word line are adjacent the gate air gap,
wherein a lower surface of the horizontal part of the gate dielectric layer is adjacent the gate air gap, and
wherein an upper surface of the gate capping layer is adjacent the gate air gap.

11. The semiconductor device of claim 1, further comprising:
a word-line protection pattern in the gate dielectric layer,
wherein the word-line protection pattern is on the first and second word lines.

12. The semiconductor device of claim 11, wherein a gate air gap is between the word-line protection pattern and the gate capping layer.

13. A semiconductor device, comprising:
a first channel structure and a second channel structure that are adjacent to each other in a first direction;
a gate dielectric layer in contact with the first and second channel structures;
a first word line on a first inner sidewall of the gate dielectric layer;
a second word line on a second inner sidewall of the gate dielectric layer; and
a gate capping layer spaced apart from the first and second word lines in a second direction that is perpendicular to the first direction,
wherein each of the first and second channel structures includes:
a first active pillar and a second active pillar that are spaced apart from each other in the first direction; and
a channel capping layer between the first and second active pillars in the first direction,
wherein the gate capping layer is in contact with the first and second inner sidewalls of the gate dielectric layer.

14. The semiconductor device of claim 13, further comprising:
a channel protection pattern that is in contact with the first active pillar, the second active pillar, and the channel capping layer; and
a channel air gap that is between the channel protection pattern and the channel capping layer,
wherein an upper surface of the channel capping layer is adjacent the channel air gap.

15. The semiconductor device of claim 14, wherein the upper surface of the channel capping layer is curved.

16. The semiconductor device of claim 14, wherein the upper surface of the channel capping layer is flat.

17. The semiconductor device of claim 14, further comprising:
a gate air gap that is surrounded by the first word line, the second word line, the gate dielectric layer, and the gate capping layer,
wherein a width of an exposed portion of a lower surface of the channel protection pattern in the first direction is greater than a width of an exposed portion of a lower surface of the gate dielectric layer in the first direction.

18. The semiconductor device of claim 13, further comprising:
a gate low-k material layer on the gate capping layer,
wherein the gate low-k material layer is in contact with the first word line, the second word line, and the gate capping layer.

19. A semiconductor device, comprising:
a bit-line structure;
a first gate structure and a second gate structure on the bit-line structure;
a first active pillar and a second active pillar between the first gate structure and the second gate structure in a first direction;
a channel capping layer between the first active pillar and the second active pillar;
a data contact that is electrically connected to each of the first and second active pillars;
a landing pad that is electrically connected to the data contact; and
a data storage pattern that is electrically connected to the landing pad,
wherein each of the first and second gate structures includes:
a first word line and a second word line that are spaced apart from each other in the first direction;
a gate dielectric layer that is in contact with the first word line and the second word line; and
a gate capping layer that is in contact with the gate dielectric layer and spaced apart from the first word line and the second word line in a second direction that is perpendicular to the first direction,
wherein a lower surface of the channel capping layer is coplanar with a lower surface of the gate capping layer.

20. The semiconductor device of claim 19, further comprising:
a channel protection pattern that is in contact with the first active pillar, the second active pillar, and the channel capping layer,
wherein a width in the first direction of the gate dielectric layer is greater than a width in the first direction of the channel protection pattern.
